(19) United States
(12) Patent Application Publication
(10) Pub. No.: US 2026/0026179 A1
(43) Pub. Date: Jan. 22, 2026

(54) Display Apparatus

(71) Applicant: LG Display Co., Ltd., Seoul (KR)

(72) Inventors: TaeYoon Kim, Seoul (KR); HyeSun Jung, Seoul (KR); BungGoo Kim, Paju-si (KR); HyoungHo Ahn, Paju-si (KR); HeeWon Lee, Paju-si (KR); JunYoung Jo, Paju-si (KR)

(21) Appl. No.: 19/211,919

(22) Filed: May 19, 2025

(30) Foreign Application Priority Data
Jul. 17, 2024 (KR) 10-2024-0094402

(51) Int. Cl. H10H 29/856; H10H 29/37

(52) U.S. Cl. CPC H10H 29/856; H10H 29/37

(57) ABSTRACT

Provided is a display apparatus. The display apparatus includes a substrate, a pixel driving circuit disposed on the substrate, a plurality of insulating layers disposed on the pixel driving circuit, a bank disposed on the plurality of insulating layers, a plurality of micro LEDs which is disposed on the bank, and is electrically connected to the pixel driving circuit, a diffusion layer which is disposed so as to enclose the bank and the plurality of micro LEDs on the plurality of insulating layers and includes a concave portion disposed along a boundary of the bank, and a reflective plate disposed on the concave portion. Accordingly, the light emission efficiency may be improved while alleviating the process difficulty so that the process optimization may be implemented.

### CROSS-REFERENCE TO RELATED APPLICATION

This application claims the priority of Republic of Korea Patent Application No. 10-2024-0094402 filed on Jul. 17, 2024, which is hereby incorporated by reference in its entirety.

### BACKGROUND

### Field

The present disclosure relates to a display apparatus.

### Description of the Related Art

Display apparatuses are being applied to various electronic devices, such as televisions (TVs), mobile phones, laptops, and tablets.

As display apparatuses, there are an organic light emitting display (OLED) device which is a self-emitting device and a liquid crystal display (LCD) device which requires a separate light source.

Recently, a display apparatus including a light emitting diode (LED) is attracting attention as a next generation display apparatus. The light emitting diode is formed of an inorganic material, rather than an organic material so that lighting speed is faster, a luminous efficiency is excellent, and an image with a higher luminance may be displayed, as compared with the liquid crystal display device or the organic light emitting display device.

### SUMMARY

An object to be achieved by the present disclosure is to provide a display apparatus with improved light extraction efficiency.

An object to be achieved by the present disclosure is to provide a display apparatus which implements process optimization to improve a light extraction efficiency while alleviating a process difficulty.

Objects of the present disclosure are not limited to the above-mentioned objects, and other objects, which are not mentioned above, can be clearly understood by those skilled in the art from the following descriptions.

An object to be achieved by the present disclosure is to provide a display apparatus with improved light extraction efficiency while maintaining a pixel integration degree.

An object to be achieved by the present disclosure is to provide a display apparatus which is driven at a low power by implementing a high luminance and a high resolution.

Objects of the present disclosure are not limited to the above-mentioned objects, and other objects, which are not mentioned above, can be clearly understood by those skilled in the art from the following descriptions.

According to an aspect of the present disclosure, a display apparatus includes a substrate, a pixel driving circuit disposed on the substrate, a plurality of insulating layers disposed on the pixel driving circuit, a bank disposed on the plurality of insulating layers, a plurality of micro LEDs which is disposed on the bank, and is electrically connected to the pixel driving circuit, a diffusion layer which is disposed on the plurality of insulating layers, and is disposed so as to enclose the bank and the plurality of micro LEDs and includes a concave portion disposed along a boundary of the bank, and a reflective plate disposed on the concave portion. Accordingly, the light emission efficiency may be improved while alleviating the process difficulty so that the process optimization may be implemented.

Other detailed matters of the exemplary embodiments are included in the detailed description and the drawings.

According to the present disclosure, a reflective plate is disposed so as to enclose the plurality of micro LEDs to improve light emission efficiency.

According to the present disclosure, the plurality of micro LEDS shares a reflective plate so that an unnecessary space required for placing the reflective plate is minimized to improve the pixel integration degree.

According to the present disclosure, a side wall diffusion layer including micro particles is omitted or is disposed only in a minimum area to alleviate the process difficulty due to the micro particles.

According to the present disclosure, the light emission efficiency is improved while alleviating the process difficulty, to improve the process optimization.

According to the present disclosure, the high luminance is implemented by improving the light extraction efficiency to improve the lifespan of the display apparatus so that the display apparatus may be driven at a low power in terms of reducing production energy.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exploded perspective view of a display apparatus according to an exemplary embodiment of the present disclosure;

FIG. 2 is a plan view of a display apparatus according to an exemplary embodiment of the present disclosure;

FIG. 3 is an enlarged view of a display apparatus according to an exemplary embodiment of the present disclosure;

FIG. 4 is a view illustrating a circuit structure according to an exemplary embodiment of the present disclosure;

FIG. 5 is a plan view of a display apparatus according to an exemplary embodiment of the present disclosure;

FIG. 6 is a plan view of a display apparatus according to an exemplary embodiment of the present disclosure;

FIG. 7 is a plan view of a display apparatus according to an exemplary embodiment of the present disclosure;

FIG. 8 is a plan view of a display apparatus according to an exemplary embodiment of the present disclosure;

FIGS. 9A and 9B are cross-sectional views of a display apparatus according to an exemplary embodiment of the present disclosure;

FIG. 10 is a cross-sectional view of a display apparatus according to an exemplary embodiment of the present disclosure;

FIG. 11 is a cross-sectional view of a display apparatus taken along the line XI-XI′ of FIG. 3 according to an exemplary embodiment of the present disclosure;

FIG. 12 is a plan view of a display apparatus according to another exemplary embodiment of the present disclosure;

FIG. 13 is a cross-sectional view of a display apparatus according to another exemplary embodiment of the present disclosure;

FIG. 14 is a plan view of a display apparatus according to still another exemplary embodiment of the present disclosure;

FIGS. 15A and 15B are cross-sectional views of a display apparatus according to still another exemplary embodiment of the present disclosure;

FIGS. 16A to 16D are process diagrams of a manufacturing method of a display apparatus according to still another exemplary embodiment of the present disclosure;

FIGS. 17A to 17D are process diagrams of a manufacturing method of a display apparatus according to still another exemplary embodiment of the present disclosure; and

FIGS. 18 to 21 are views illustrating devices to which a display apparatus according to exemplary embodiments of the present disclosure is applied.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When explaining temporal relationships, terms such as “after,” “following,” “subsequent to,” or “before,” etc., may include non-consecutive cases unless terms like “immediately” or “directly” are used.

Terms such as “first,” “second,” etc. are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) may be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component may be directly connected, coupled, joined, or attached to the other component, but unless explicitly specified otherwise, it may also be indirectly connected, coupled, joined, or attached with another component intervening between each component.

When a component or layer is described as being “in contact with” or “overlapping” another component or layer, the component or layer may directly contact or overlap the other component or layer, but unless explicitly specified otherwise, it should be understood that it may also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The terms “first direction”, “second direction”, “third direction”, “X-axis direction”, “Y-axis direction”, and “Z-axis direction” should not be interpreted solely as geometric relationships perpendicular to each other, but may indicate broader directionality within the range where the configuration of the present disclosure can function.

The features of various embodiments in the present disclosure may be partially or wholly combined or associated with each other, various technical interlocking and operations are possible, and each embodiment may be implemented independently of each other or may be implemented together in an associated relationship.

Hereinafter, a display apparatus according to exemplary embodiments of the present disclosure will be described in detail with reference to accompanying drawings.

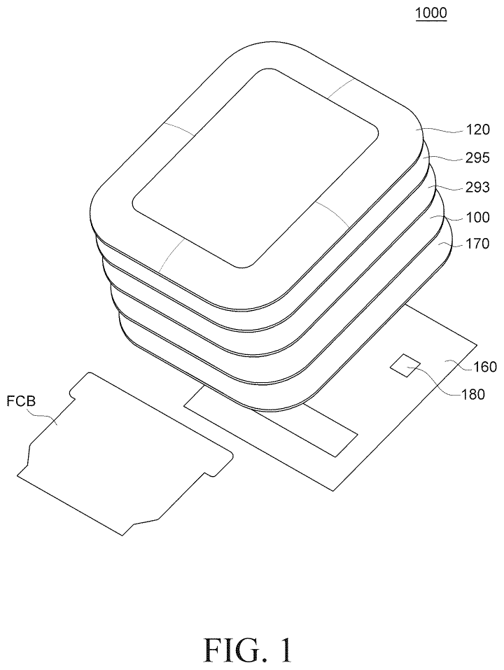

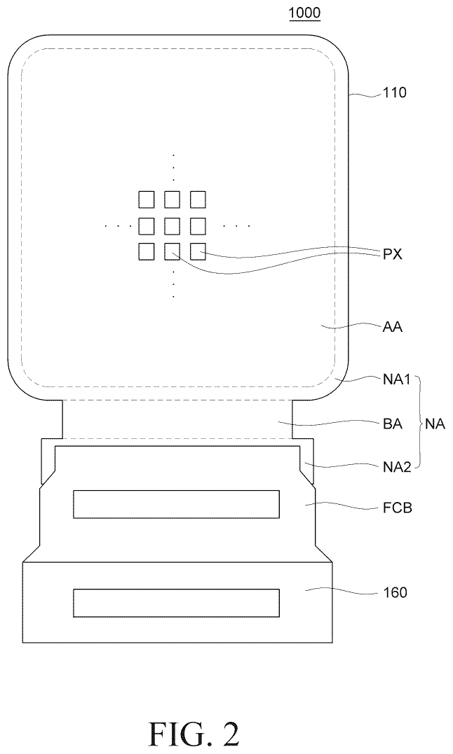

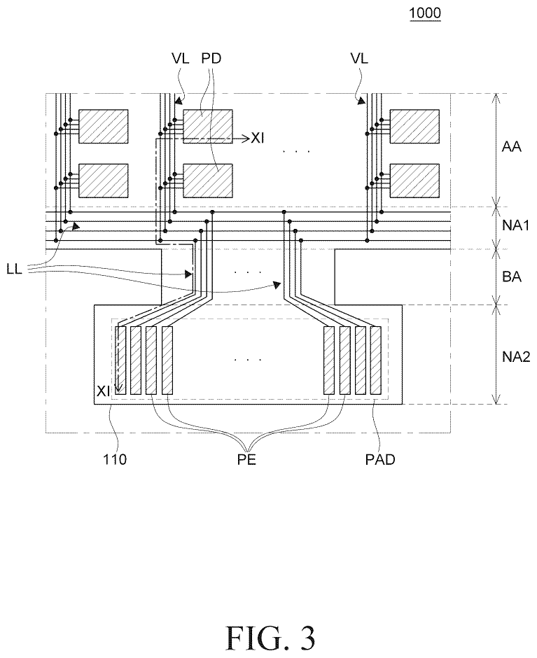

FIG. 1 is a perspective view illustrating a display apparatus according to an exemplary embodiment of the present disclosure. FIG. 2 is a plan view of a display apparatus according to an exemplary embodiment of the present disclosure. FIG. 3 is an enlarged view of a display apparatus according to an exemplary embodiment of the present disclosure.

Referring to FIGS. 1 to 3, a display apparatus 1000 according to an exemplary embodiment of the present disclosure may include a display panel 100, a polarization layer 293, an adhesive layer 295, a cover member 120, a support substrate 170, a flexible circuit board FCB, and a printed circuit board 160.

For example, the display panel 100 of the display apparatus 1000 may include a substrate 110. The substrate 110 may be a member which supports other components of the display apparatus 1000. The substrate 110 may be formed of an insulating material. For example, the substrate 110 may be formed of glass or resin. Further, the substrate 110 may also be formed of a material having a flexibility. For example, the substrate 110 may be formed of an organic insulating material which is a plastic material having flexibility, such as polyimide (PI). However, the exemplary embodiments of the present disclosure are not limited thereto.

The display panel 100 may implement information, videos, and/or images which are provided to users. For example, the display panel 100 may include an active area AA and a non-active area NA. For example, the substrate 110 may include an active area AA and a non-active area NA which encloses the active area AA. However, the active area AA and the non-active area NA are not mentioned to be limited to the substrate 110, but may be mentioned for the entire display apparatus 1000.

The active area AA may be an area where images are displayed. The active area AA may include a plurality of pixels PX. Each of the plurality of pixels PX may be configured by a plurality of sub pixels. A plurality of micro LEDs may be disposed in each of the plurality of sub pixels.

The non-active area NA may be an area where no image is displayed. In the non-active area NA, various wiring lines and circuits for driving the plurality of pixels PX of the active area AA may be disposed. For example, in the non-active area NA, various wiring lines and driving circuits may be mounted and a pad unit PAD to which an integrated circuit and a printed circuit are connected may be disposed, but the exemplary embodiments of the present disclosure are not limited thereto.

For example, the driving circuit may be a data driving circuit and/or a gate driving circuit, but the exemplary embodiments of the present disclosure are not limited thereto. Wiring lines through which a control signal for controlling driving circuits is supplied may be disposed. For example, the control signal may include various timing signals including a clock signal, an input data enable signal, and synchronization signals, but the exemplary embodiments of the present disclosure are not limited thereto. The control signal may be received through the pad unit PAD. For example, in the non-active area NA, link lines LL may be disposed to transmit signals. For example, driving components, such as the flexible circuit board FCB and the printed circuit board 160, may be connected to the pad unit PAD.

According to the present disclosure, the non-active area NA may include a first non-active area NA1, a bending area BA, and a second non-active area NA2. For example, the first non-active area NA1 may be an area which encloses at least a part of the active area AA. The bending area BA may be an area extending from at least one side, among a plurality of sides of the first non-active area NA1 and may be a bendable area. The second non-active area NA2 may be an area extending from the bending area BA and the pad unit PAD may be disposed therein. For example, the bending area BA may be in a bent state and the other areas of the substrate 110 excluding the bending area BA may be in a flat state. In this case, as the bending area BA is bent, the second non-active area NA2 may be located on a rear surface of the active area AA. However, the exemplary embodiments of the present disclosure are not limited thereto.

The active area AA of the substrate 110 or the display apparatus 1000 may be configured with various shapes depending on a design of the display apparatus 1000. For example, the active area AA may be configured with a rectangular shape formed with four rounded corners, but the exemplary embodiments of the present disclosure are not limited thereto. As another example, the active area AA may be configured with a rectangular shape formed with four right-angled corners or a circular shape, but the exemplary embodiments of the present disclosure are not limited thereto.

According to the present disclosure, a width of the second non-active area NA2 in which the plurality of pad electrodes PE are disposed may be larger than a width of the bending area BA in which a plurality of link lines LL are disposed. Further, a width of the active area AA in which the plurality of sub pixels are disposed may be larger than a width of the bending area BA in which a plurality of link lines LL are disposed. Even though in the drawing, it is illustrated that the width of the bending area BA is smaller than a width of the other area of the substrate 110, the shape of the substrate 110 including the bending area BA is illustrative and the exemplary embodiments of the present disclosure are not limited thereto.

A plurality of pixel driving circuits PD may be disposed on the substrate 110. Referring to FIG. 3, a plurality of pixel driving circuits PD may be disposed in the active area AA. The plurality of pixel driving circuits PD may be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD may include a power line and a signal line for controlling emission on/off of the micro LED and/or an emission time. For example, the plurality of pixel driving circuits PD may be driving drivers manufactured using a metal-oxide-silicon field effect transistor (MOSFET) manufacturing process on a semiconductor substrate, but the exemplary embodiments of the present disclosure are not limited thereto. The driving driver may include a plurality of pixel driving circuits PD and drive a plurality of sub pixels.

Referring to FIG. 1 together, the flexible circuit board FCB and the printed circuit board 160 may be disposed below the display panel 100. The flexible circuit board FCB and the printed circuit board 160 may be disposed at least at one edge of the display panel 100, but the exemplary embodiments of the present disclosure are not limited thereto. One side of the flexible circuit board FCB may be attached to the display panel 100 and the other side may be attached to the printed circuit board 160, but the exemplary embodiments of the present disclosure are not limited thereto. The flexible circuit board FCB may be a flexible film, but the exemplary embodiments of the present disclosure are not limited thereto.

A pad unit PAD including a plurality of pad electrodes PE may be disposed in the second non-active area NA2. In the pad unit PAD, a driving component including one or more flexible circuit boards (or flexible films) FCB and the printed circuit board 160 may be attached or bonded. The plurality of pad electrodes PE of the pad unit PAD may be electrically connected to one or more flexible circuit boards (or flexible films) FCB and transmit various signals (or powers) from the printed circuit board 160 and the flexible circuit board (or a flexible film) FCB to the plurality of pixel driving circuits PD of the active area AA.

The flexible circuit board (or flexible film) FCB may be a film on which various components are disposed on a base film having ductility. For example, driving integrated circuits (ICs) such as a gate driver IC or a data driver IC may be disposed in the flexible circuit board (or flexible film) FCB, but the exemplary embodiments of the present disclosure are not limited thereto. The driving IC may be a component which processes data and driving signals to display images. The driving IC may be disposed by a chip on glass (COG), a chip on film (COF), or a tape carrier package (TCP) technique depending on a mounting method, but the exemplary embodiments of the present disclosure are not limited thereto. The flexible circuit board (or flexible film) FCB may be attached or bonded onto the plurality of pad electrodes PE through a conductive adhesive layer, but the exemplary embodiments of the present disclosure are not limited thereto.

The printed circuit board 160 may be a component which is electrically connected to one or more flexible circuit boards (or flexible films) FCB and supplies a signal to the driving IC. The printed circuit board 160 is disposed at one side of the flexible circuit board (or flexible film) FCB to be electrically connected to the flexible circuit board (or flexible film) FCB. On the printed circuit board 160, various components for supplying various signals to the driving IC may be disposed. For example, on the printed circuit board 160, various components, such as a timing controller, a power source, a memory, or a processor, may be disposed. For example, the printed circuit board 160 may include a power management integrated circuit (PMIC), but the exemplary embodiments of the present disclosure are not limited thereto.

The printed circuit board 160 may include at least one hole 180, but the exemplary embodiments of the present disclosure are not limited thereto. An internal component which senses ambient light or temperature to be supplied to a plurality of sensors may be disposed in an area corresponding to at least one hole 180. For example, the internal component may include an ambient light sensor (ALS) or a temperature sensor, but the exemplary embodiments of the present disclosure are not limited thereto. For example, the hole 180 may be a transmission hole, but the exemplary embodiments of the present disclosure are not limited thereto.

Referring to FIG. 1, a polarization layer 293 may be disposed on the display panel 100. The polarization layer 293 may suppress or reduce the influence on the micro LED caused by light generated from an external light source and entering the display panel 100.

A cover member 120 may be disposed on the polarization layer 293. The cover member 120 may be a member for protecting the display panel 100. The adhesive layer 295 may be disposed between the polarization layer 293 and the cover member 120. The cover member 120 may be attached to the display panel 100 using the adhesive layer 295. An adhesive layer 295 may include an optically clear adhesive (OCA), an optically clear resin (OCR), or a pressure sensitive adhesive (PSA), but the exemplary embodiments of the present disclosure are not limited thereto.

A support substrate 170 may be disposed between the display panel 100 and the printed circuit board 160. The support substrate 170 may reinforce a rigidity of the display panel 100. The support substrate 170 may be a back plate, but the exemplary embodiments of the present disclosure are not limited thereto.

Referring to FIGS. 1 to 3, the plurality of link lines LL may be disposed in the non-active area NA. The plurality of link lines LL may be wiring lines which transmit various signals from one or more flexible circuit boards (or flexible films) FCB and the printed circuit board 160 to the active area AA. The plurality of link lines LL extend from the plurality of pad electrodes PE of the second non-active area NA2 toward the bending area BA and the first non-active area NA1 to be electrically connected to the plurality of driving lines VL of the active area AA. The plurality of pixel driving circuits PD may be supplied with signals from one or more flexible circuit boards (or flexible films) FCB and the printed circuit board 160 through the driving line VL of the active area AA and the link line LL of the non-active area NA to be driven.

For example, the plurality of driving lines VL may be wiring lines for transmitting a signal output from the flexible circuit board (or flexible film) FCB and the printed circuit board 160 to the plurality of pixel driving circuits PD together with the plurality of link lines LL. The plurality of driving lines VL are disposed in the active area AA to be electrically connected to each of the plurality of pixel driving circuits PD. The plurality of driving lines VL extend toward the non-active area NA from the active area AA to be electrically connected to the plurality of link lines LL. Accordingly, a signal output from the flexible circuit board (or flexible film) FCB and the printed circuit board 160 may be transmitted to each of the plurality of pixel driving circuits PD through the plurality of link lines LL and the plurality of driving lines VL.

As the bending area BA is bent, parts of the plurality of link lines LL may be bent together. A stress is concentrated in the bent part of the link line LL, which may cause a crack on the link line LL. Accordingly, the plurality of link lines LL may be configured by a conductive material having excellent ductility to reduce the crack caused when the bending area BA is bent. For example, the plurality of link lines LL may be configured by a conductive material having excellent ductility, such as gold (Au), silver (Ag), or aluminum (Al), but the exemplary embodiments of the present disclosure are not limited thereto. Further, the plurality of link lines LL may be configured by one of various conductive materials used for the active area AA. For example, the plurality of link lines LL may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto. The plurality of link lines LL may be configured by a multi-layered structure including various conductive materials. For example, the plurality of link lines LL may be configured with a triple-layered structure of titanium (Ti)/aluminum (Al)/titanium (Ti), but the exemplary embodiments of the present disclosure are not limited thereto.

The plurality of link lines LL may be configured with various shapes to reduce a stress. At least parts of the plurality of link lines LL disposed on the bending area BA may extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA may extend in an inclined direction from the one direction. As another example, at least parts of the plurality of link lines LL may be configured by various shapes of patterns. For example, at least parts of the plurality of link lines LL disposed on the bending area BA may have a shape in which a conductive pattern having at least one shape of a diamond shape, a rhombus shape, a trapezoidal wave shape, a triangular wave shape, a sawtooth wave shape, a sine wave shape, a circular shape, an omega (Ω) shape may be repeatedly disposed. However, the exemplary embodiments of the present disclosure are not limited thereto. Accordingly, in order to minimize or reduce a stress concentrated on the plurality of link lines LL and a crack caused thereby, a shape of the plurality of link lines LL may be various shapes including the above-mentioned shapes, but the exemplary embodiments of the present disclosure are not limited thereto.

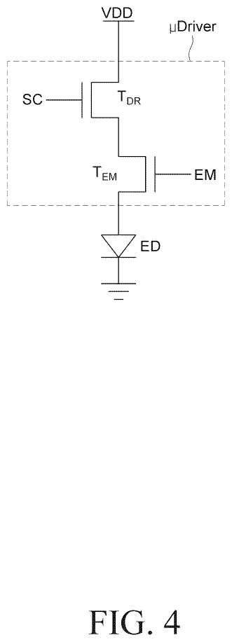

FIG. 4 is a view illustrating a circuit structure according to an exemplary embodiment of the present disclosure.

A pixel driving circuit PD may include a micro driver μDriver. The micro LED ED is electrically connected to the micro driver μDriver of the pixel driving circuit PD to be driven. Even though in FIG. 4, it is illustrated that one micro LED ED is connected to one micro driver μDriver, but the present disclosure is not limited thereto. For example, eight micro LEDs ED may be connected to one micro driver μDriver. As another example, 16 micro LEDs ED may be connected to one micro driver μDriver or 32 micro LEDs ED or 64 micro LEDs ED may be simultaneously connected to one micro driver μDriver. The micro LED ED may be a micro micro LED (μLED).

One micro driver μDriver may include a driving transistor T_{DR} and an emission transistor T_{EM}, but the exemplary embodiments of the present disclosure are not limited thereto.

For example, a high potential power voltage VDD may be applied to a first electrode of the driving transistor T_{DR} and a first electrode of the emission transistor T_{EM} may be connected to a second electrode of the driving transistor T_{DR}, and a scan signal SC may be applied to a gate electrode of the driving transistor T_{DR}. The scan signal SC applied to the gate electrode of the driving transistor T_{DR} is a direct current (DC) power and a fixed reference voltage may be applied in every frame, but the exemplary embodiments of the present disclosure are not limited thereto.

The second electrode of the driving transistor T_{DR} may be connected to a first electrode of the emission transistor T_{EM}, the first electrode of the micro LED ED may be connected to a second electrode of the emission transistor T_{EM}, and the emission signal EM may be applied to a gate electrode of the emission transistor T_{EM}. The emission signal EM applied to the gate electrode of the emission transistor T_{EM} may be a pulse width modulation signal which changes in every frame, but the exemplary embodiments of the present disclosure are not limited thereto.

A first electrode of the micro LED ED may be connected to the second electrode of the emission transistor T_{EM} and a second electrode of the micro LED ED may be connected to the ground. For example, the first electrode of the micro LED ED may be an anode electrode and the second electrode of the micro LED ED may be a cathode electrode, but the exemplary embodiments of the present disclosure are not limited thereto.

Each of the driving transistor T_{DR} and the emission transistor T_{EM} may be an n-type transistor or a p-type transistor.

The driving transistor T_{DR} may be turned on by a scan signal SC applied from the timing controller T-CON (not shown) to the micro driver μDriver and the emission transistor T_{EM} may be turned on by the emission signal EM applied from the timing controller T-CON to the micro driver μDriver. By doing this, the driving current is applied to the micro LED ED via the driving transistor T_{DR} and the emission transistor T_{EM} by the high potential power voltage VDD applied to the first electrode of the driving transistor T_{DR} so that the micro LED ED may emit light.

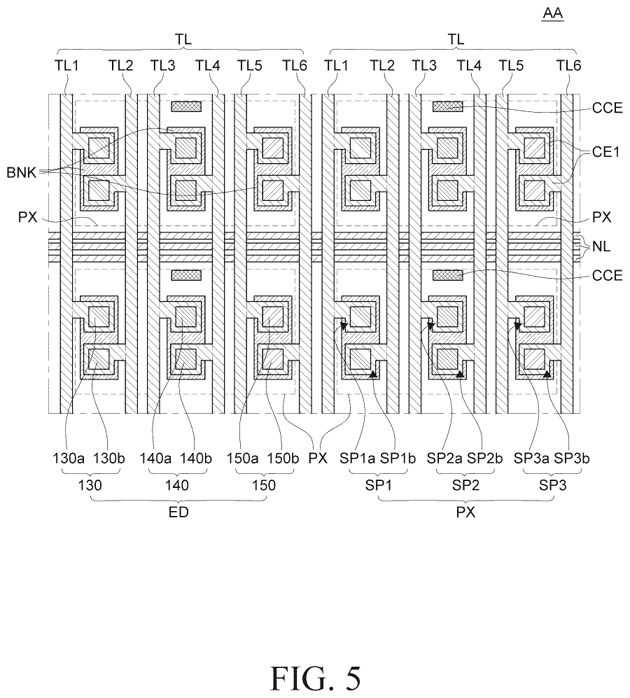

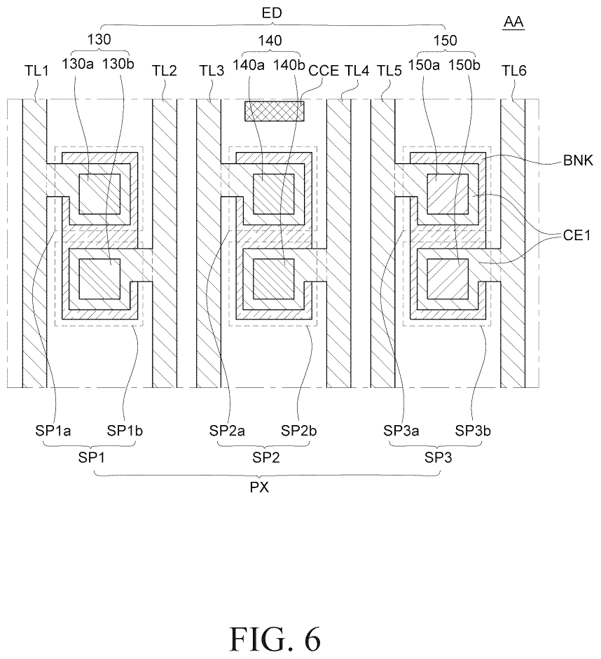

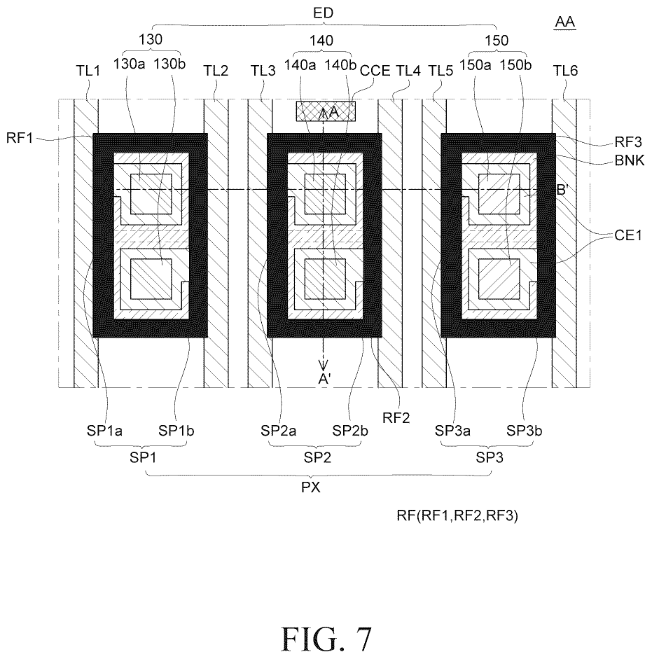

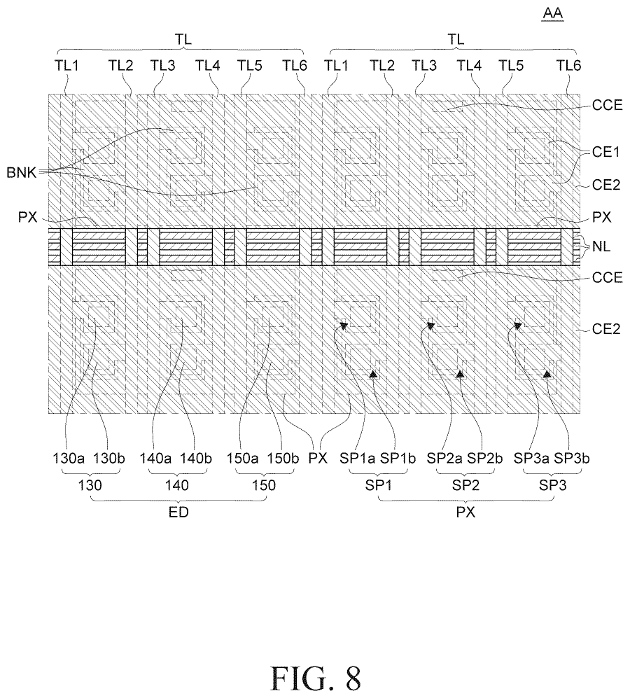

FIGS. 5 to 8 are plan views of a display apparatus according to an exemplary embodiment of the present disclosure. For example, FIG. 5 is an enlarged plan view of an active area including a plurality of pixels ording to an exemplary embodiment of the present disclosure. For example, FIG. 6 is an enlarged plan view of an active area including one pixel ording to an exemplary embodiment of the present disclosure. For example, FIG. 7 is an enlarged plan view in which a plurality of reflective plates RF (e.g., the reflective plates RF1 to RF3) is added in FIG. 6 ording to an exemplary embodiment of the present disclosure. For example, FIG. 8 is an enlarged plan view of an active area including a plurality of pixels ording to an exemplary embodiment of the present disclosure. In FIGS. 5 and 7, a plurality of signal lines TL (e.g., the signal lines TL1 to TL6), a plurality of communication lines NL, a plurality of first electrodes CE1, a plurality of banks BNK, a plurality of micro LEDs ED, and a plurality of reflective plates RF are illustrated, but the exemplary embodiments of the present disclosure are not limited thereto. FIG. 8 is an enlarged plan view in which a plurality of second electrodes CE2 is additionally disposed to FIG. 5.

Referring to FIGS. 5 and 6, a plurality of pixels PX which is configured by a plurality of sub pixels may be disposed in the active area AA. Each of the plurality of sub pixels includes a micro LED ED and may independently emit light. The plurality of sub pixels may be disposed in a matrix by forming a plurality of rows and a plurality of columns, but the exemplary embodiments of the present disclosure are not limited thereto.

The plurality of sub pixels may include a first sub pixel SP1, a second sub pixel SP2, and a third sub pixel SP3. For example, any one of the first sub pixel SP1, the second sub pixel SP2, and the third sub pixel SP3 may be a red sub pixel, another may be a green sub pixel, and the third may be a blue sub pixel. The types of the plurality of sub pixels are illustrative, but the exemplary embodiments of the present disclosure are not limited thereto.

Each of the plurality of pixels PX may include one or more first sub pixels SP1, one or more second sub pixels SP2, and one or more third sub pixels SP3. For example, one pixel PX may include one pair of first sub pixels SP1, one pair of second sub pixels SP2, and one pair of third sub pixels SP3. One pair of first sub pixels SP1 may be configured by a 1-1-th sub pixel SP1a and a 1-2-th sub pixel SP1b. One pair of second sub pixels SP2 may be configured by a 2-1-th sub pixel SP2a and a 2-2-th sub pixel SP2b. One pair of third sub pixels SP3 may be configured by a 3-1-th sub pixel SP3a and a 3-2-th sub pixel SP3b. For example, one pixel PX may include a 1-1-th sub pixel SP1a and a 1-2-th sub pixel SP1b, a 2-1-th sub pixel SP2a and a 2-2-th sub pixel SP2b, and a 3-1-th sub pixel SP3a and a 3-2-th sub pixel SP3b, but the exemplary embodiments of the present disclosure are not limited thereto.

The plurality of sub pixels which forms one pixel PX may be disposed in various ways. For example, in one pixel PX, one pair of first sub pixels SP1 may be disposed on the same column, one pair of second sub pixels SP2 may be disposed on the same column, and one pair of third sub pixels SP3 may be disposed on the same column. The first sub pixels SP1, the second sub pixels SP2, and the third sub pixels SP3 may be disposed on the same row. A number and a placement of the plurality of sub pixels which configures one pixel PX are illustrative, but the exemplary embodiments of the present disclosure are not limited thereto.

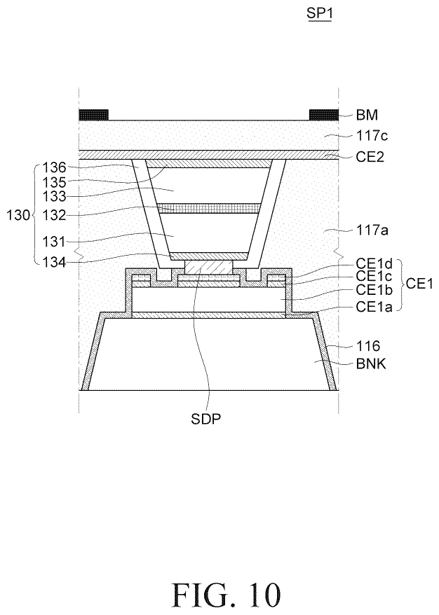

The plurality of signal lines TL may be disposed in an area between the plurality of sub pixels. The plurality of signal lines TL may extend in the column direction between the plurality of sub pixels. The plurality of signal lines TL may be wiring lines which transmit an anode voltage from the pixel driving circuit PD to the plurality of sub pixels. For example, the plurality of signal lines TL may be electrically connected to the plurality of pixel driving circuits PD and the first electrodes CE of the plurality of sub pixels. The anode voltage output from the pixel driving circuit PD may be transmitted to the first electrode CE1 of the plurality of sub pixels through the plurality of signal lines TL. A plurality of the first electrodes CE1 may be electrically connected to the plurality of micro LEDs, respectively. For example, the first electrode CE1 may be an electrode which is electrically connected to the anode electrode 134 (referring to FIG. 10) of the micro LED ED. Therefore, the anode voltage from the signal line TL may be transmitted to the anode electrode 134 of the micro LED ED through the first electrode CE1.

Accordingly, instead of the plurality of transistors and storage capacitors formed in each of the plurality of sub pixels, a pixel driving circuit PD in which a plurality of pixel circuits is integrated is used to simplify the structure of the display apparatus 1000. Further, a circuit which is disposed in each of the plurality of sub pixels is integrated in one pixel driving circuit PD so that highly efficient low power driving is possible.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to one pair of first sub pixels SP1, respectively. The third signal line TL3 and the fourth signal line TL4 may be electrically connected to one pair of second sub pixels SP2, respectively. The fifth signal line TL5 and the sixth signal line TL6 may be electrically connected to one pair of third sub pixels SP3, respectively.

The first signal line TL1 may be disposed on one of one pair of first sub pixels SP1 and the second signal line TL2 may be disposed on another one of one pair of first sub pixels SP1. The first signal line TL1 may be electrically connected to one first sub pixel SP1, between one pair of first sub pixels SP1, for example, to the first electrode CE1 of the 1-1-th sub pixel SP1a. The second signal line TL2 may be electrically connected to the other first sub pixel SP1, between one pair of first sub pixels SP1, for example, to the first electrode CE1 of the 1-2-th sub pixel SP1b.

The third signal line TL3 may be disposed on one of one pair of second sub pixels SP2 and the fourth signal line TL4 may be disposed on another one of one pair of second sub pixels SP2. For example, the third signal line TL3 may be disposed to be adjacent to the second signal line TL2. The third signal line TL3 may be electrically connected to one second sub pixel SP2, between one pair of second sub pixels SP2, for example, to the first electrode CE1 of the 2-1-th sub pixel SP2a. The fourth signal line TL4 may be electrically connected to the other second sub pixel SP2, between one pair of second sub pixels SP2, for example, to the first electrode CE1 of the 2-2-th sub pixel SP2b.

The fifth signal line TL5 may be disposed on one of one pair of third sub pixels SP3 and the sixth signal line TL6 may be disposed on another one of one pair of third sub pixels SP3. For example, the fifth signal line TL5 may be disposed to be adjacent to the fourth signal line TL4. The sixth signal line TL6 may be disposed to be adjacent to the first signal line TL1 connected to the adjacent pixel PX. The fifth signal line TL5 may be electrically connected to one third sub pixel SP3, between one pair of third sub pixels SP3, for example, to the first electrode CE1 of the 3-1-th sub pixel SP3a. The sixth signal line TL6 may be electrically connected to the other third sub pixel SP3, between one pair of third sub pixels SP3, for example, to the first electrode CE1 of the 3-2-th sub pixel SP3b.

The plurality of signal lines TL may be formed of a conductive material. For example, the plurality of signal lines TL may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the plurality of signal lines TL may be formed with a multi-layered structure of conductive materials. For example, the plurality of signal lines TL may be formed with a multi-layered structure of titanium (Ti)/aluminum (Al)/titanium (Ti)/indium tin oxide (ITO), but the exemplary embodiments of the present disclosure are not limited thereto.

A plurality of communication lines NL may be disposed in an area between the plurality of pixels PX. The plurality of communication lines NL may be disposed to extend in the row direction in an area between the plurality of pixels PX. The plurality of communication lines NL may be disposed in the area between the plurality of second electrodes CE2 and may not overlap the plurality of second electrodes CE2. For example, the plurality of communication lines NL may be wiring lines used for short distance communication, such as near field communication (NFC). The plurality of communication lines NL may serve as antennas. For example, the plurality of communication lines NL may be a plurality of connection lines, but the exemplary embodiments of the present disclosure are not limited thereto.

According to the present disclosure, a bank BNK may be disposed in each of the plurality of sub pixels. The plurality of banks BNK may be structures in which the plurality of micro LEDs ED is seated. The plurality of banks BNK may guide a position of the plurality of micro LEDs ED during a transfer process of transferring the plurality of micro LEDs ED to the display apparatus 1000. The plurality of micro LEDs ED may be transferred onto the plurality of banks BNK in the transfer process of the plurality of micro LEDs ED. The plurality of banks BNK may be a bank pattern or a structure, but the exemplary embodiments of the present disclosure are not limited thereto.

A bank BNK of the first sub pixel SP1, a bank BNK of the second sub pixel SP2, and a bank BNK of the third sub pixel SP3 may be disposed to be spaced apart from each other. The bank BNK of the first sub pixel SP1, the bank BNK of the second sub pixel SP2, and the bank BNK of the third sub pixel SP3 may be configured to be separated from each other. Therefore, the banks BNK of the first sub pixel SP1, the second sub pixel SP2, and the third sub pixel SP3 to which different types of micro LEDs ED are transferred may be easily identified.

The bank BNK of the 1-1-th sub pixel SP1a and the bank BNK of the 1-2-th sub pixel SP1b may be connected to each other or spaced apart or separated from each other. For example, in consideration of a design, such as a transfer process requirement, the bank BNK of the 1-1-th sub pixel SP1a and the bank BNK of the 1-2-th sub pixel SP1b in which the same type of micro LED ED is disposed may be connected to each other or spaced apart or separated from each other. The bank BNK of the 2-1-th sub pixel SP2a and the bank BNK of the 2-2-th sub pixel SP2b may be connected to each other, spaced apart or separated from each other. The bank BNK of the 3-1-th sub pixel SP3a and the bank BNK of the 3-2-th sub pixel SP3b may be connected to each other, spaced apart or separated from each other. Accordingly, the banks BNK of one pair of first sub pixels SP1, the banks BNK of one pair of second sub pixels SP2, and the banks BNK of third sub pixels SP3 may be formed in various forms, but the exemplary embodiments of the present disclosure are not limited thereto.

For example, the plurality of banks BNK may be formed of an organic insulating material. The plurality of banks BNK may be configured by a single layer or a double layer of an organic insulating material. For example, the plurality of banks BNK may be configured by a photo resist, polyimide (PI), or acrylic material, but the exemplary embodiments of the present disclosure are not limited thereto.

The first electrode CE1 may be disposed in each of the plurality of sub pixels. The first electrode CE1 may be disposed on the bank BNK. The first electrode CE1 may be electrically connected to one signal line TL, among the plurality of signal lines TL. At least a part of the first electrode CE1 extends to the outside of the bank BNK to be electrically connected to the signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL1. A part of the first electrode CE1 of the 1-2-th sub pixel SP1b extends to the other area of the 1-2-th sub pixel SP1b to be electrically connected to the second signal line TL2. A part of the first electrode CE1 of the 2-1-th sub pixel SP2a extends to one area of the 2-1-th sub pixel SP2a to be electrically connected to the third signal line TL3. A part of the first electrode CE1 of the 2-2-th sub pixel SP2b extends to the other area of the 2-2-th sub pixel SP2b to be electrically connected to the fourth signal line TLA. A part of the first electrode CE1 of the 3-1-th sub pixel SP3a extends to one area of the 3-1-th sub pixel SP3a to be electrically connected to the fifth signal line TL5. A part of the first electrode CE1 of the 3-2-th sub pixel SP3b extends to the other area of the 3-2-th sub pixel SP3b to be electrically connected to the sixth signal line TL6.

The first electrode CE1 may be electrically connected to the anode electrode 134 of the micro LED ED and transmit an anode voltage from the pixel driving circuit PD to the micro LED ED through the signal line TL. Different voltages may be applied to the first electrodes CE1 of the plurality of sub pixels depending on the image to be displayed. For example, different voltages may be applied to the first electrodes CE1 of the plurality of sub pixels. Therefore, the first electrode CE1 may be a pixel electrode, but the exemplary embodiments of the present disclosure are not limited thereto.

The first electrode CE1 may be configured by a conductive material. For example, the first electrode CE1 may be integrally configured with the plurality of signal lines TL. For example, the first electrode CE1 may be configured by the same conductive material as the plurality of signal lines TL, but the exemplary embodiments of the present disclosure are not limited thereto. For example, the first electrode CE1 may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the exemplary embodiments of the present disclosure are not limited thereto. As another example, the first electrode CE1 may be configured by a multi-layered structure of conductive materials. For example, the plurality of first electrodes CE1 may be configured by a multi-layered structure of titanium (Ti)/aluminum (Al)/titanium (Ti)/indium tin oxide (ITO), but the exemplary embodiments of the present disclosure are not limited thereto.

The micro LED ED may be disposed in the plurality of sub pixels, respectively. A plurality of micro LEDs ED may be disposed on the bank BNK, and is electrically connected to the pixel driving circuit PD. The plurality of micro LEDs ED may be disposed on the bank BNK and the first electrode CE1. The plurality of micro LEDs ED may be disposed on the first electrode CE1 and may be electrically connected to the first electrode CE1. Accordingly, the micro LED ED is applied with an anode voltage from the pixel driving circuit PD through the signal line TL and the first electrode CE1 to emit light.

The plurality of micro LEDs ED may include a first micro LED 130, a second micro LED 140, and a third micro LED 150. The first micro LED 130 may be disposed in the first sub pixel SP1. The second micro LED 140 may be disposed in the second sub pixel SP2. The third micro LED 150 may be disposed in the third sub pixel SP3. For example, any one of the first micro LED 130, the second micro LED 140, and the third micro LED 150 may be a red micro LED, another may be a green micro LED, and the third may be a blue micro LED, but the exemplary embodiments of the present disclosure are not limited thereto. Therefore, red light, green light, and blue light emitted from the plurality of micro LEDs ED are combined to implement various color light including white. The types of the plurality of micro LEDs ED are illustrative, but the exemplary embodiments of the present disclosure are not limited thereto.

The first micro LED 130 may include a 1-1-th micro LED 130a disposed in the 1-1-th sub pixel SP1a and a 1-2-th micro LED 130b disposed in the 1-2-th sub pixel SP1b. The second micro LED 140 may include a 2-1-th micro LED 140a disposed in the 2-1-th sub pixel SP2a and a 2-2-th micro LED 140b disposed in the 2-2-th sub pixel SP2b. The third micro LED 150 may include a 3-1-th micro LED 150a disposed in the 3-1-th sub pixel SP3a and a 3-2-th micro LED 150b disposed in the 3-2-th sub pixel SP3b.

Referring to FIG. 7, the plurality of reflective plates RF may be disposed so as to enclose the plurality of micro LEDs ED. The plurality of reflective plates RF may be disposed along a boundary or an outer contour of the bank BNK. Accordingly, the plurality of reflective plates RF may extend in a first direction (e.g., the column direction) and be spaced apart from each other in a second direction (e.g., a row direction) which is the same as the bank BNK, but is not limited thereto.

The plurality of reflective plates RF are disposed so as to be adjacent to side surfaces of the plurality of micro LEDs ED to reflect light which is emitted from the plurality of micro LEDs ED to be directed to the side surface of the plurality of micro LEDs ED to be directed to the front surface of the plurality of micro LEDs ED to improve a light extraction efficiency.

Specifically, the plurality of reflective plates RF may include a first reflective plate RF1, a second reflective plate RF2, and a third reflective plate RF3 which are spaced apart from each other in each of the first sub pixel SP1, the second sub pixel SP2, and the third sub pixel SP3.

For example, the first reflective plate RF1 may be disposed so as to enclose the 1-1-th micro LED 130a and the 1-2-th micro LED 130b disposed in the first sub pixel SP1. That is, the 1-1-th micro LED 130a and the 1-2-th micro LED 130b disposed in the first sub pixel SP1 may share the first reflective plate RF1, but are not limited thereto.

The second reflective plate RF2 may be disposed so as to enclose the 2-1-th micro LED 140a and the 2-2-th micro LED 140b disposed in the second sub pixel SP2. The 2-1-th micro LED 140a and the 2-2-th micro LED 140b disposed in the second sub pixel SP2 may share the second reflective plate RF2, but are not limited thereto.

The third reflective plate RF3 may be disposed so as to enclose the 3-1-th micro LED 150a and the 3-2-th micro LED 150b disposed in the third pixel SP3. That is, the 3-1-th micro LED 150a and the 3-2-th micro LED 150b disposed in the third sub pixel SP3 may share the third reflective plate RF3, but are not limited thereto.

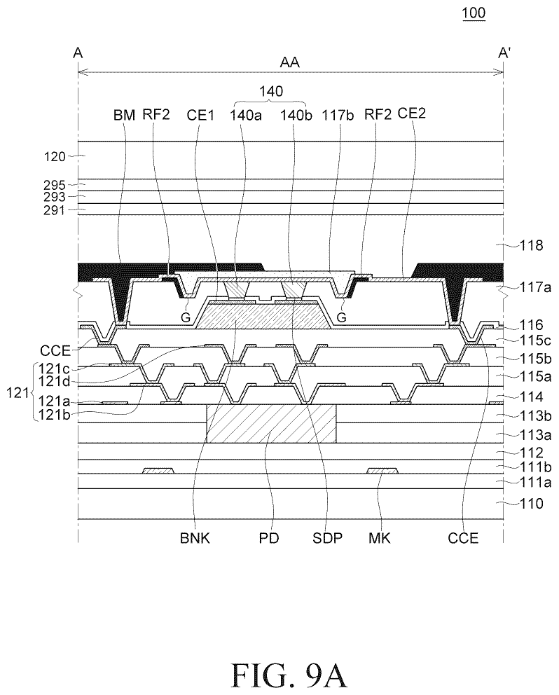

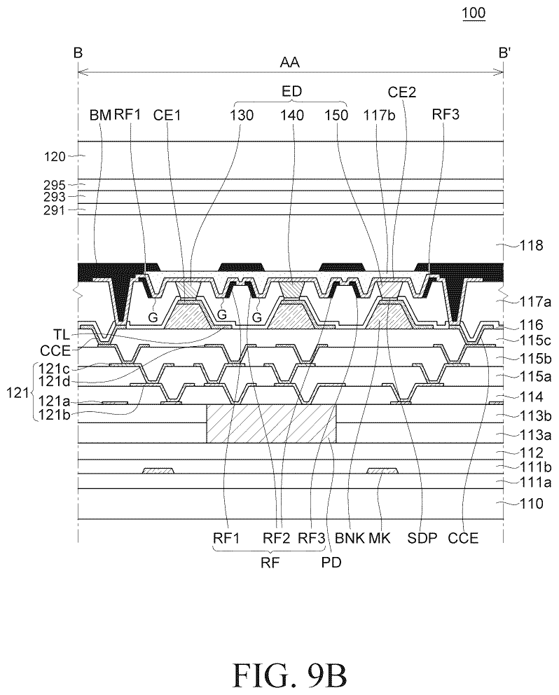

A specific content of the plurality of reflective plates RF will be described in detail with reference to FIG. 9A to be described below.

Referring to FIGS. 5 to 8 together, the second electrode CE2 may be disposed in each of the plurality of sub pixels. The second electrode CE2 may be disposed on the micro LED ED and the plurality of reflective plates RF. The second electrode CE2 may be electrically connected to the pixel driving circuit PD through the plurality of contact electrodes CCE.

For example, the second electrode CE2 is electrically connected to the cathode electrode 135 (referring to FIG. 10) of the micro LED ED to transmit a cathode voltage from the pixel driving circuit PD to the micro LED ED. The same cathode voltage may be applied to the second electrodes CE2 of the plurality of sub pixels. For example, the same voltage may be applied to the second electrode CE2 of each of the plurality of sub pixels and the cathode electrode 135 of the micro LED ED. Therefore, the second electrode CE2 may be a common electrode, but the exemplary embodiments of the present disclosure are not limited thereto.

At least some of the plurality of sub pixels may share the second electrode CE2. At least some of the second electrodes CE2 of the plurality of sub pixels may be electrically connected to each other. As the same voltage is applied to the second electrode CE2, the second electrodes CE2 of at least some of sub pixels may be shared and used. For example, the second electrodes CE2 of at least some pixels PX, among the plurality of pixels PX disposed on the same row, may be connected to each other. For example, one second electrode CE2 may be disposed in the plurality of pixels PX. One second electrode CE2 may be disposed in every n sub pixels.

For example, some of the second electrodes CE2 of the plurality of sub pixels may be spaced apart or separated from each other. For example, a second electrode CE2 connected to pixels PX in an n-th row and a second electrode CE2 connected to pixels PX in an n+1-th row may be spaced apart or separated from each other. For example, the plurality of second electrodes CE2 may be spaced apart from each other with the plurality of communication lines NL extending in the row direction therebetween. Accordingly, the number of the plurality of sub pixels may be larger than the number of the plurality of second electrodes CE2. As another example, all the second electrodes CE2 of the plurality of sub pixels are connected to each other so that only one second electrode CE2 may be disposed on the substrate 110, but the exemplary embodiments of the present disclosure are not limited thereto.

The plurality of second electrodes CE2 may be configured by a transparent conductive material, but the exemplary embodiments of the present disclosure are not limited thereto. The plurality of second electrodes CE2 are configured by a transparent conductive material so that light emitted from the micro LED ED may travel toward the top of the second electrode CE2. For example, the second electrode CE2 may be configured by a transparent conductive material, such as indium tin oxide (ITO), indium zinc oxide (IZO), indium gallium zinc oxide (IGZO), but the exemplary embodiments of the present disclosure are not limited thereto.

A plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap a plurality of contact electrodes CCE.

For example, the plurality of contact electrodes CCE may be electrically connected to the plurality of second electrodes CE2. The plurality of contact electrodes CCE are disposed between the substrate 110 and the plurality of second electrodes CE2 to transmit a cathode voltage from the pixel driving circuit PD to the second electrode CE2.

For example, when a micro LED ED is used as the micro LED ED, a plurality of micro LEDs may be formed on a wafer and the micro LED may be transferred onto the substrate 110 of the display apparatus 1000 to manufacture the display apparatus 1000. However, during the process of transferring the plurality of micro LEDs ED having a micro size from the wafer to the substrate 110, various defects may be caused. For example, in some sub pixels, a non-transfer defect in which the micro LED is not transferred may occur and in the other sub pixel, a defect that the micro LED ED is transferred in a wrong position may occur due to the alignment error. Further, even though the transfer process is normally performed, the transferred micro LED ED may be defective. Accordingly, in consideration of the defects during the transfer process of the plurality of micro LEDs ED, a plurality of same type micro LEDs may be transferred in one sub pixel. A lighting test for the plurality of micro LEDs ED is performed and one micro LED ED which is finally determined to be normal may be used.

For example, the 1-1-th micro LED 130a and the 1-2-th micro LED 130b are transferred to one pixel PX together and defects thereof may be tested. If both the 1-1-th micro LED 130a and the 1-2-th micro LED 130b are determined to be normal, the 1-1-th micro LED 130a may be used, but the 1-2-th micro LED 130b may not be used. As another example, if the 1-2-th micro LED 130b between the 1-1-th micro LED 130a and the 1-2-th micro LED 130b is determined to be normal, the 1-1-th micro LED 130a may not be used, but the 1-2-th micro LED 130b may be used. Accordingly, even though the plurality of same type micro LEDs ED is transferred to one pixel PX, finally, only one micro LED ED may be used.

Therefore, any one of one pair of micro LEDs ED may be a main (or primary) micro LED ED and the other micro LED ED) may be a redundancy micro LED ED. The redundancy micro LED ED may be an extra micro LED ED which is transferred to prepare for a defect of the main micro LED ED. When the main micro LED ED is defective, the redundancy micro LED ED may be used instead. Accordingly, the main micro LED ED and the redundancy micro LED ED are transferred together to one pixel PX so that the degradation of the display quality due to the defects of the main micro LED ED and the redundancy micro LED ED may be minimized.

For example, a 1-1-th micro LED 130a, a 2-1-th micro LED 140a, and a 3-1-th micro LED 150a which are transferred to one pixel PX may be used as main micro LEDs ED and a 1-2-th micro LED 130b, a 2-2-th micro LED 140b, and a 3-2-th micro LED 150b may be used as redundancy micro LEDs ED, but are not limited thereto.

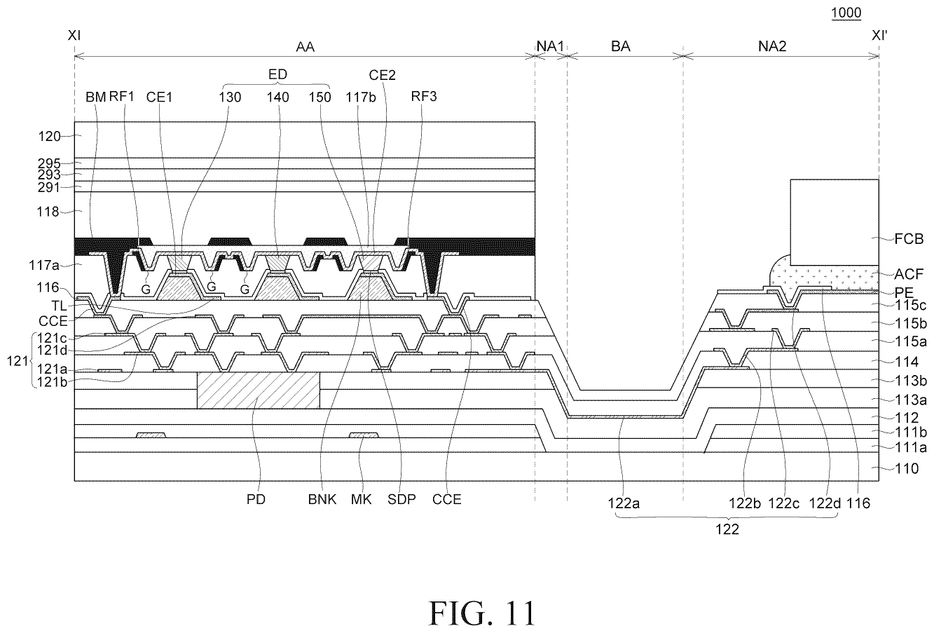

FIGS. 9A to 11 are cross-sectional views of a display apparatus according to an exemplary embodiment of the present disclosure. For example, FIG. 9A is a cross-sectional view of an active area AA taken along A-A′ of FIG. 7 according to an exemplary embodiment of the present disclosure. For example, FIG. 9B is a cross-sectional view of an active area AA taken along B-B′ of FIG. 7 according to an exemplary embodiment of the present disclosure. For example, FIG. 10 is an enlarged cross-sectional view of a first sub pixel SP1 according to an exemplary embodiment of the present disclosure. For example, FIG. 11 is a cross-sectional view taken along XI-XI′ of FIG. 3 according to an exemplary embodiment of the present disclosure. Referring to FIGS. 9A, 9B, and 11, a first buffer layer 111a and a second buffer layer 111b may be disposed in the remaining area of the substrate 110 excluding the bending area BA.

The first buffer layer 111a and the second buffer layer 111b may be disposed in the active area AA, the first non-active area NA1, and the second non-active area NA2. The first buffer layer 111a and the second buffer layer 111b may reduce permeation of moisture or impurities through the substrate 110. The first buffer layer 111a and the second buffer layer 111b may be formed of an inorganic insulating material. For example, the first buffer layer 111a and the second buffer layer 111b may be configured by a single layer or multiple layers of silicon oxide (SiOx) or silicon nitride (SiNx), but the exemplary embodiments of the present disclosure are not limited thereto.

For example, the first buffer layer 111a and the second buffer layer 111b on the bending area BA may be partially removed. A top surface of the substrate 110 located in the bending area BA may be exposed from the first buffer layer 111a and the second buffer layer 111b. The first buffer layer 111a and the second buffer layer 111b which are formed of an inorganic insulating material are removed from the bending area BA to minimize or at least reduce cracks of the first buffer layer 111a and the second buffer layer 111b which may be generated during the bending.

A plurality of alignment keys MK may be disposed between the first buffer layer 111a and the second buffer layer 111b. The plurality of alignment keys MK may be configured to identify a position of the pixel driving circuit PD during the manufacturing process of the display apparatus 1000. For example, the plurality of alignment keys MK may be configured to align a position of the pixel driving circuit PD which is transferred onto the adhesive layer 112. As another example, the plurality of alignment keys MK may be omitted.

The adhesive layer 112 may be disposed on the second buffer layer 111b. The adhesive layer 112 may be disposed in the active area AA, the first non-active area NA1, the bending area BA, and the second non-active area NA2. As another example, in the non-active area NA including the bending area BA, at least a part of the adhesive layer 112 may be removed. For example, the adhesive layer 112 may be formed of any one of adhesive polymer, epoxy resin, UV curable resin, polyimide based, acrylate based, urethane based, and polydimethylsiloxane (PDMS), but the exemplary embodiments of the present disclosure are not limited thereto.

The pixel driving circuit PD may be disposed on the adhesive layer 112 in the active area AA. When the pixel driving circuit PD is implemented as a driving driver, the driving driver may be mounted on the adhesive layer 112 by the transfer process, but the exemplary embodiments of the present disclosure are not limited thereto.

A first protection layer 113a and a second protection layer 113b may be disposed on the adhesive layer 112 and the pixel driving circuit PD. The first protection layer 113a and the second protection layer 113b may be disposed so as to enclose a side surface of the pixel driving circuit PD, but the exemplary embodiments of the present disclosure are not limited thereto. For example, the second protection layer 113b may be disposed so as to cover at least a part of a top surface of the pixel driving circuit PD. For example, at least one of the first protection layer 113a and the second protection layer 113b disposed on the bending area BA may be omitted. For example, the first protection layer 113a may be entirely disposed in the active area AA and the non-active area NA and the second protection layer 113b may be partially disposed in the active area AA, the first non-active area NA1, and the second non-active area NA2. For example, a part of the second protection layer 113b in the bending area BA may be removed. However, the exemplary embodiments of the present disclosure are not limited thereto.

The first protection layer 113a and the second protection layer 113b may be configured by an organic insulating material, but the exemplary embodiments of the present disclosure are not limited thereto. For example, the first protection layer 113a and the second protection layer 113b may be configured by a photo resist, polyimide (PI), or photo acrylic material, but the exemplary embodiments of the present disclosure are not limited thereto. For example, the first protection layer 113a and the second protection layer 113b may be over coating layers or insulating layers, but the exemplary embodiments of the present disclosure are not limited thereto.

According to the present disclosure, in the active area AA, the plurality of first connection lines 121 may be disposed on the second protection layer 113b. The plurality of first connection lines 121 may be wiring lines which electrically connect the pixel driving circuit PD to the other component. For example, the pixel driving circuit PD may be electrically connected to the plurality of signal lines TL and the plurality of contact electrodes CCE through the plurality of first connection lines 121. For example, the plurality of first connection lines 121 may include a 1-1-th connection line 121a, a 1-2-th connection line 121b, a 1-3-th connection line 121c, and a 1-4-th connection line 121b, but the exemplary embodiments of the present disclosure are not limited thereto.

For example, the plurality of 1-1-th connection lines 121a may be disposed on the second protection layer 113b. The plurality of 1-1-th connection lines 121a may be electrically connected to the pixel driving circuit PD. The plurality of 1-1-th connection lines 121a may transmit a voltage output from the pixel driving circuit PD to the first electrode CE or the second electrode CE2.

For example, a third protection layer 114 may be disposed on the second protection layer 113b. The third protection layer 114 may be entirely disposed in the active area AA and the non-active area NA. In the bending area BA, the third protection layer 114 may cover a side surface of the second protection layer 113b and the top surface of the first protection layer 113a. The third protection layer 114 may be configured by an organic insulating material. For example, the third protection layer 114 may be configured by a photo resist, polyimide (PI), or photo acrylic material, but the exemplary embodiments of the present disclosure are not limited thereto. For example, the first protection layer 113a, the second protection layer 113b, and the third protection layer 114 may be configured by the same material, but the exemplary embodiments of the present disclosure are not limited thereto.

The plurality of 1-2-th connection lines 121b may be disposed on the third protection layer 114. The plurality of 1-2-th connection lines 121b may be indirectly or directly connected to the pixel driving circuit PD. For example, a part of the 1-2-th connection line 121b may be directly connected to the pixel driving circuit PD through a contact hole of the third protection layer 114. The other part of the 1-2-th connection line 121b may be electrically connected to the 1-1-th connection line 121a through the contact hole of the third protection layer 114. However, the exemplary embodiments of the present disclosure are not limited thereto. A voltage output from the pixel driving circuit PD may be transmitted to the first electrode CE1 or the second electrode CE2 through a connection line other than the plurality of 1-2-th connection lines 121b.

A plurality of insulating layers may be disposed on the pixel driving circuit PD. The first insulating layer 115a may be disposed on the plurality of 1-2-th connection lines 121b. The first insulating layer 115a may be entirely disposed in the active area AA and the non-active area NA, but the exemplary embodiments of the present disclosure are not limited thereto. The first insulating layer 115a may be configured by an organic insulating material, but the exemplary embodiments of the present disclosure are not limited thereto. For example, the first insulating layer 115a may be configured by a photo resist, polyimide (PI), or photo acrylic material, but the exemplary embodiments of the present disclosure are not limited thereto.

The plurality of 1-3-th connection lines 121c may be disposed on the first insulating layer 115a. The plurality of 1-3-th connection lines 121c may be electrically connected to the plurality of 1-2-th connection lines 121b. For example, the 1-3-th connection lines 121c may be electrically connected to the 1-2-th connection lines 121b through a contact hole of the first insulating layer 115a.

The second insulating layer 115b may be disposed on the plurality of 1-3-th connection lines 121c. The second insulating layer 115b may be disposed in a remaining area excluding the bending area BA, but the exemplary embodiments of the present disclosure are not limited thereto. The second insulating layer 115b may be disposed in the active area AA, the first non-active area NA1, and the second non-active area NA2, but the exemplary embodiments of the present disclosure are not limited thereto. For example, a part of the second insulating layer 115b disposed in the bending area BA may be removed. The second insulating layer 115b may be configured by an organic insulating material, but the exemplary embodiments of the present disclosure are not limited thereto. For example, the second insulating layer 115b may be configured by a photo resist, polyimide (PI), or photo acrylic material, but the exemplary embodiments of the present disclosure are not limited thereto.

The plurality of 1-4-th connection lines 121d may be disposed on the second insulating layer 115b. The plurality of 1-4-th connection lines 121d may be electrically connected to the plurality of 1-3-th connection lines 121c. For example, the 1-4-th connection lines 121d may be electrically connected to the 1-3-th connection lines 121c through a contact hole of the second insulating layer 115b.

According to the present disclosure, in the non-active area NA, the plurality of second connection lines 122 may be disposed on the second protection layer 113b. The plurality of second connection lines 122 may be wiring lines which transmit a signal transmitted from the flexible circuit board (or flexible film) FCB and the printed circuit board 160 (see FIG. 1) to the pad unit PAD to the pixel driving circuit PD of the active area AA. For example, the plurality of second connection lines 122 are electrically connected to the plurality of pad electrodes PE to be applied with a signal from the flexible circuit board (or flexible film) FCB and the printed circuit board.

For example, the plurality of second connection lines 122 extend toward the active area AA from the pad unit PAD to transmit a signal to the wiring line of the active area AA. In this case, the plurality of second connection lines 122 may serve as a link line LL. The plurality of second connection lines 122 may include a 2-1-th connection line 122a, a 2-2-th connection line 122b, a 2-3-th connection line 122c, and a 2-4-th connection line 122d.

A plurality of 2-1-th connection lines 122a may be disposed on the second protection layer 113b. The plurality of 2-1-th connection lines 122a may extend from the second non-active area NA2 to the bending area BA and the first non-active area NA1. The plurality of 2-1-th connection lines 122a may transmit a signal transmitted from the flexible circuit board (or flexible film) FCB and the printed circuit board 160 to the pad unit PAD to the pixel driving circuit PD of the active area AA.

A plurality of 2-2-th connection lines 122b may be disposed on the third protection layer 114. The plurality of 2-2-th connection lines 122b may be disposed in the second non-active area NA2. The 2-2-th connection line 122b may be electrically connected to the 2-1-th connection line 122a through the contact hole of the third protection layer 114. Accordingly, a signal from the flexible circuit board (or flexible film) FCB and the printed circuit board may be transmitted to the 2-1-th connection line 122a through the 2-2-th connection line 122b.

The 2-3-th connection line 122c may be disposed on the first insulating layer 115a. The 2-3-th connection line 122c may be disposed in the second non-active area NA2. The 2-3-th connection line 122c may be electrically connected to the 2-2-th connection line 122b through a contact hole of the first insulating layer 115a. Accordingly, a signal from the flexible circuit board (or flexible film) FCB and the printed circuit board may be transmitted to the 2-1-th connection line 122a through the 2-3-th connection line 122c and the 2-2-th connection line 122b.

The 2-4-th connection line 122d may be disposed on the second insulating layer 115b. The 2-4-th connection line 122d may be disposed in the second non-active area NA2. The 2-4-th connection line 122d may be electrically connected to the 2-3-th connection line 122c through a contact hole of the second insulating layer 115b. Accordingly, a signal from the flexible circuit board (or flexible film) FCB and the printed circuit board 160 may be transmitted to the 2-1-th connection line 122a through the 2-4-th connection line 122d, the 2-3-th connection line 122c, and the 2-2-th connection line 122b.

The plurality of first connection lines 121 and the plurality of second connection lines 122 may be formed of any one of a conductive material having excellent ductility or various conductive materials used for the active area AA. For example, the second connection line 122 which is partially disposed in the bending area BA may be configured by a conductive material having excellent ductility, such as gold (Au), silver (Ag), or aluminum (Al), but the exemplary embodiments of the present disclosure are not limited thereto. As another example, the plurality of first connection lines 121 and the plurality of second connection lines 122 may be configured by molybdenum (Mo), chrome (Cr), titanium (Ti), nickel (Ni), neodymium (Nd), copper (Cu), and an alloy of silver (Ag) and magnesium (Mg) or an alloy thereof, but the exemplary embodiments of the present disclosure are not limited thereto.

The third insulating layer 115c may be disposed on the plurality of first connection lines 121 and the plurality of second connection lines 122. The third insulating layer 115c may be disposed in a remaining area excluding the bending area BA, but the exemplary embodiments of the present disclosure are not limited thereto. The third insulating layer 115c may be disposed in the active area AA, the first non-active area NA1, and the second non-active area NA2. A part of the third insulating layer 115c disposed in the bending area BA may be removed. The third insulating layer 115c may be configured by an organic insulating material, but the exemplary embodiments of the present disclosure are not limited thereto. For example, the third insulating layer 115c may be configured by a photo resist, polyimide (PI), or photo acrylic material, but the exemplary embodiments of the present disclosure are not limited thereto.

A plurality of banks BNK may be disposed on the plurality of insulating layers. The plurality of banks BNK may be disposed on the third insulating layer 115c in the active area AA. The plurality of banks BNK may be disposed so as to overlap each of the plurality of sub pixels. One or more same type micro LEDs ED may be disposed above each of the plurality of banks BNK.

A plurality of signal lines TL may be disposed on the third insulating layer 115c in the active area AA. The plurality of signal lines TL may be disposed in an area between the plurality of banks BNK. For example, the plurality of signal lines TL may be disposed to be adjacent to any one of the plurality of banks BNK.

A plurality of contact electrodes CCE may be disposed on the third insulating layer 115c in the active area AA. The plurality of contact electrodes CCE may supply a cathode voltage from the pixel driving circuit PD to the second electrode CE2.

The first electrode CE1 may be disposed on the bank BNK. For example, the first electrode CE1 may be disposed to extend toward the top of the bank BNK from the adjacent signal line TL. The first electrode CE1 may be disposed on the top surface of the bank BNK and the side surface of the bank BNK. For example, the first electrode CE1 may be disposed to extend from the signal line TL on the top surface of the third insulating layer 115c to the side surface of the bank BNK and the top surface of the bank BNK.

Referring to FIG. 10, the first electrode CE1 may be configured by a plurality of conductive layers. For example, the first electrode CE1 may include a first conductive layer CE1a, a second conductive layer CE1b, a third conductive layer CE1c, and a fourth conductive layer CE1d, but the exemplary embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may be configured by titanium (Ti), molybdenum (Mo), aluminum (Al), or titanium (Ti) and indium tin oxide (ITO), but the exemplary embodiments of the present disclosure are not limited thereto.

According to the present disclosure, some conductive layers having a good reflection efficiency, among a plurality of conductive layers which configure the first electrode CE1 may be configured as an alignment key for alignment of the micro LED ED and/or a reflective plate. For example, the second conductive layer CE1b, among the plurality of conductive layers of the first electrode CE1, may include a reflective material. For example, the second conductive layer CE1b may include aluminum (Al), but the exemplary embodiments of the present disclosure are not limited thereto. Therefore, the second conductive layer CE1b may be configured as a reflective plate. Further, the second conductive layer CE1b has a high reflection efficiency to be easily identified during the manufacturing process so that a position of the micro LED ED or a transfer position may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, a part of the third conductive layer CE1c and the fourth conductive layer CE1d disposed on the bank BNK is removed or etched to expose a top surface of the second conductive layer CE1b. For example, a center portion and an edge portion (or a boundary portion) of the third conductive layer CE1c and the fourth conductive layer CE1d in which a solder pattern SDP is disposed remain and the remaining portion excluding the portions may be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 may be suppressed.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has a good adhesiveness with the solder pattern SDP, and has anti-corrosion and acid-resistance. However, the exemplary embodiments of the present disclosure are not limited thereto.

The first conductive layer CE1a, the second conductive layer CE1b, the third conductive layer CE1c, and the fourth conductive layer CE1d are sequentially deposited, and then are subject to a photolithographic process and an etching process to be patterned. However, the exemplary embodiments of the present disclosure are not limited thereto.

According to the present disclosure, the signal line TL, the contact electrode CCE, and the pad electrode PE disposed on the same layer as the first electrode CE1 may be configured by multiple layers of conductive materials, but the exemplary embodiments of the present disclosure are not limited thereto. For example, the signal line TL, the contact electrode CCE, and the pad electrode PE may be formed of multiple layers of indium tin oxide (ITO)/titanium (Ti)/aluminum (Al)/titanium (Ti), but the exemplary embodiments of the present disclosure are not limited thereto.

According to the present disclosure, in each of the plurality of sub pixels, a solder pattern SDP may be disposed on the first electrode CE1. The solder pattern SDP may be disposed between the first electrode CE1 and the anode electrode 134 of the micro LED ED and bond the micro LED ED to the first electrode CE1. The first electrode CE1 and the micro LED ED may be electrically connected through eutectic bonding using the solder pattern SDP, but the exemplary embodiments of the present disclosure are not limited thereto. For example, when the solder pattern SDP is configured by indium (In) and the anode electrode 134 of the micro LED ED is configured by gold (Au), during the transfer process of the micro LED ED, heat and pressure are applied to bond the solder pattern SDP and the anode electrode 134. The micro LED ED may be bonded to the first electrode CE1 by the eutectic bonding using the solder pattern SDP without a separate adhesive material. For example, the solder pattern SDP may be configured by indium (Id), tin (Sn), or an alloy thereof, but the exemplary embodiments of the present disclosure are not limited thereto. For example, the solder pattern SDP may be a bonding pad or an adhesive pad, but the exemplary embodiments of the present disclosure are not limited thereto.

According to the present disclosure, the passivation layer 116 may be disposed on the plurality of signal lines TL, the plurality of first electrodes CE1, the plurality of contact electrodes CCE, and the third insulating layer 115c. For example, the passivation layer 116 may be disposed in the active area AA, the first non-active area NA1, and the second non-active area NA2. A part of the passivation layer 116 disposed in the bending area BA may be removed. A part of the passivation layer 116 which covers a plurality of pad electrodes PE in the second non-active area NA2 may be removed. The passivation layer 116 is disposed so as to cover the remaining area excluding the bending area BA, the plurality of pad electrodes PE, and the solder pattern SDP to reduce permeation of moisture or impurities entering the micro LED ED. For example, the passivation layer 116 may be configured by a single layer or multiple layers of silicon oxide (SiOx) or silicon nitride (SiNx), but the exemplary embodiments of the present disclosure are not limited thereto. For example, the passivation layer 116 may be a protection layer or an insulating layer, but the exemplary embodiments of the present disclosure are not limited thereto. For example, the passivation layer 116 may include a hole through which the solder pattern SDP is exposed.

In each of the plurality of sub pixels, the micro LED ED may be disposed on the solder pattern SDP. A first micro LED 130 may be disposed in the first sub pixel SP1. A second micro LED 140 may be disposed in the second sub pixel SP2. A third micro LED 150 may be disposed in the third sub pixel SP3.

The micro LED ED may be formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the exemplary embodiments of the present disclosure are not limited thereto.

Referring to FIG. 10, taking the first micro LED 130 as an example, each of the micro LEDs ED may include an anode electrode 134, a first semiconductor layer 131 disposed on the anode electrode 134, an active layer 132 disposed on the first semiconductor layer 131, a second semiconductor layer 133 disposed on the active layer 132, a cathode electrode 135 disposed on the second semiconductor layer 133 and has a vertical type structure, and an encapsulation film 136, but the exemplary embodiments of the present disclosure are not limited thereto. For example, the encapsulation film 136 may not be included in the first micro LED 130.

The first semiconductor layer 131 may be disposed on the solder pattern SDP. The second semiconductor layer 133 may be disposed over the first semiconductor layer 131.

For example, one of the first semiconductor layer 131 and the second semiconductor layer 133 may be implemented by a compound semiconductor, such as a III-V group or a II-VI group and may be doped with an impurity (or dopant). For example, one of the first semiconductor layer 131 and the second semiconductor layer 133 may be an n-type impurity-doped semiconductor layer and the other one may be a p-type impurity-doped semiconductor, but the exemplary embodiments of the present disclosure are not limited thereto. For example, one or more of the first semiconductor layer 131 and the second semiconductor layer 133 may be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the exemplary embodiments of the present disclosure are not limited thereto. For example, the n-type impurity may be silicon (Si), germanium (Ge), selenium (Se), carbon (C), tellurium (Te), or tin (Sn), but the exemplary embodiments of the present disclosure are not limited thereto. For example, the p-type impurity may be magnesium (Mg), zinc (Zn), calcium (Ca), strontium (Sr), barium (Ba), or beryllium (Be), but the exemplary embodiments of the present disclosure are not limited thereto.

For example, each the first semiconductor layer 131 and the second semiconductor layer 133 may be a nitride semiconductor including an n-type impurity or a nitride semiconductor including a p-type impurity, but the exemplary embodiments of the present disclosure are not limited thereto. For example, the first semiconductor layer 131 may be a nitride semiconductor including a p-type impurity and the second semiconductor layer 133 may be a nitride semiconductor including an n-type impurity, but the exemplary embodiments of the present disclosure are not limited thereto.

The active layer 132 may be disposed between the first semiconductor layer 131 and the second semiconductor layer 133. The active layer 132 may be supplied with holes and electrons from the first semiconductor layer 131 and the second semiconductor layer 133 to emit light. For example, the active layer 132 may be configured by one of a single well structure, a multi-well structure, a signal quantum well structure, a multi-quantum well (MQC) structure, a quantum dot structure, and a quantum line structure, but the exemplary embodiments of the present disclosure are not limited thereto. For example, the active layer 132 may be configured by indium gallium nitride (InGaN) or gallium nitride (GaN), but the exemplary embodiments of the present disclosure are not limited thereto.

As another example, the active layer 132 may have a multi quantum well (MQW) structure having a well layer and a barrier layer with a band gap higher than the well layer. For example, in the active layer 132, InGaN may be configured as a well layer and an AlGaN layer may be configured as a barrier layer, but the exemplary embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be configured by a conductive material which may form eutectic bonding with the solder pattern SDP, but the exemplary embodiments of the present disclosure are not limited thereto. For example, the anode electrode 134 may be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the exemplary embodiments of the present disclosure are not limited thereto.

The cathode electrode 135 may be disposed on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be configured by a transparent conductive material to allow light emitted from the micro LED ED to be directed to the top of the micro LED ED, but the exemplary embodiments of the present disclosure are not limited thereto. For example, the cathode electrode 135 may be configured by a material, such as indium tin oxide (ITO), indium zinc oxide (IZO), or indium gallium zinc oxide (IGZO), but the exemplary embodiments of the present disclosure are not limited thereto.

The encapsulation film 136 may be disposed in at least parts of the first semiconductor layer 131, the active layer 132, the second semiconductor layer 133, the anode electrode 134, and the cathode electrode 135. For example, the encapsulation film 136 may enclose at least parts of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least parts of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 is exposed from the encapsulation film 136 so that the anode electrode 134 and the solder pattern SDP may be connected. For example, at least a part of the cathode electrode 135 is exposed from the encapsulation film 136 so that the cathode electrode 135 and the second electrode CE2 may be connected. For example, the encapsulation film 136 may be formed of an insulating material, such as silicon nitride (SiNx) or silicon oxide (SiOx), but the exemplary embodiments of the present disclosure are not limited thereto.

As another example, the encapsulation film 136 may have a structure in which a reflective material is dispersed in a resin layer, but the exemplary embodiments of the present disclosure are not limited thereto. For example, the encapsulation film 136 may be manufactured with reflectors (reflective plates) with various structures, but the exemplary embodiments of the present disclosure are not limited thereto. Light emitted from the active layer 132 is upwardly reflected by the encapsulation film 136 so that light extraction efficiency may be improved. For example, the encapsulation film 136 may be a reflective layer, but the exemplary embodiments of the present disclosure are not limited thereto.

According to the present disclosure, the micro LED ED is described to have a vertical type structure, but the exemplary embodiments of the present disclosure are not limited thereto. For example, the micro LED ED may have a lateral structure or a flip-chip structure.

The first micro LED 130 has been described with reference to FIG. 10 and the second micro LED 140 and the third micro LED 150 may have substantially the same structure as the first micro LED 130. For example, the second micro LED 140 and the third micro LED 150 may be substantially the same as the first semiconductor layer 131, the active layer 132, the second semiconductor layer 133, the anode electrode 134, the cathode electrode 135, and the encapsulation film 136 of the first micro LED 130.

According to the present disclosure, a diffusion layer 117a may be disposed in the active area AA. The diffusion layer 117a may be disposed so as to enclose the bank BNK and the plurality of micro LEDs ED. The diffusion layer 117a may be disposed on the plurality of insulating layers and the bank BNK and may be disposed so as to enclose the plurality of micro LEDs. For example, the diffusion layer 117a may be disposed so as to cover the plurality of micro LEDs ED and the bank BNK in the area of the plurality of sub pixels. For example, the diffusion layer 117a may cover a bank BNK, a part of the passivation layer 116 and between the plurality of micro LEDs ED. The diffusion layer 117a may be disposed or cover between the plurality of micro LEDs ED and between the plurality of banks BNK included in one pixel PX.

For example, the diffusion layer 117a may extend in a row direction and may be spaced apart in a column direction. For example, the diffusion layer 117a may be disposed so as to enclose side portions of the micro LED ED and the bank BNK between the passivation layer 116 and the second electrode CE2, but the exemplary embodiments of the present disclosure are not limited thereto. For example, the diffusion layer 117a may be an optical layer, a diffusion window, or a window diffusion layer, but the exemplary embodiments of the present disclosure are not limited thereto.

For example, the diffusion layer 117a may be disposed in each of the plurality of pixels PX or disposed in some pixels PX disposed in the same row together, but the exemplary embodiments of the present disclosure are not limited thereto. For example, the diffusion layer 117a may be disposed in each of the plurality of pixels PX or the plurality of pixels PX may share one diffusion layer 117a. As another example, each of the plurality of sub pixels may separately include the diffusion layer 117a, but the exemplary embodiments of the present disclosure are not limited thereto.

For example, the diffusion layer 117a may be configured by an organic insulating material, but may not include micro particles, and the exemplary embodiments of the present disclosure are not limited thereto.

In the meantime, the diffusion layer 117a may include concave portions G. The concave portions G may be disposed along a boundary or an outer contour of the bank BNK. A plurality of concave portions G may be disposed so as to correspond to an outer contour of each of the plurality of banks BNK on a plane. Therefore, the plurality of concave portions G may be disposed so as to enclose two micro LEDs ED disposed on the bank BNK, together.

The reflective plates RF may be disposed on the concave portions G of the diffusion layer 117a. The plurality of reflective plates RF may be disposed on the plurality of concave portions G of the diffusion layer 117a, respectively. The plurality of reflective plates RF are disposed so as to enclose the side surface of the micro LED ED to reflect light which is emitted from the light emitting diode ED to be directed to the side surface. That is, the plurality of reflective plates RF change the optical path to allow the light which is directed to the side surface to be directed to the front surface to improve the light emission efficiency.

Therefore, the reflective plates RF may be disposed in a light emission path of the micro LED ED. For example, the reflective plates RF may be disposed on a side surface which is further from the micro LED ED, of the two side surfaces of the concave portions G. For example, referring to FIG. 9A, in a concave portion G disposed on the right side of the second micro LED 140, the second reflective plate RF2 may be disposed on a side surface located on the right side, between both side surfaces of the concave portion. Further, in a concave portion G disposed on a left side of the second micro LED 140, the second reflective plate RF2 may be disposed on a side surface located on the left side, between both side surfaces of the concave portion. That is, the plurality of reflective plates RF may be disposed on a side surface which is spaced apart from the micro LED ED, between both side surfaces of the plurality of concave portions G, but is not limited thereto.

In the meantime, the plurality of reflective plates RF may extend to a top surface of the diffusion layer 117a, but is not limited thereto. For example, referring to FIG. 9A, in the concave portion G disposed on the right side of the second micro LED 140, the second reflective plate RF2 may extend to a top surface of the diffusion layer 117a disposed on the right side of the concave portion G. In the concave portion G disposed on the left side, the second reflective plate RF2 may extend to a top surface of the diffusion layer 117a disposed on the left side of the concave portion G, but is not limited thereto.

The plurality of reflective plates RF may be formed of a conductive material having good reflectance. For example, the plurality of reflective plates may be formed of aluminum (Al), but is not limited thereto.

In the meantime, the plurality of reflective plates RF are disposed on the plurality of concave portions G disposed along a boundary of the bank BNK to be disposed so as to simultaneously enclose two micro LEDs ED disposed on the same bank BNK. That is, the plurality of micro LEDs ED include two micro LEDs ED which are disposed on the bank BNK and emit the same color. The reflective plate is disposed so as to enclose the two micro LEDs ED. That is, two micro LEDs ED which are disposed on the same bank BNK and emit the same color light may share the plurality of reflective plates RF.

For example, referring to FIG. 7 together, the first reflective plate RF1 may be disposed so as to enclose the 1-1-th micro LED 130a and the 1-2-th micro LED 130b disposed on the same bank BNK and emitting the same color. Accordingly, the 1-1-th micro LED 130a and the 1-2-th micro LED 130b may share the first reflective plate RF1.

The second reflective plate RF2 is disposed so as to enclose the 2-1-th micro LED 140a and the 2-2-th micro LED 140b disposed on the same bank BNK and emitting the same color. Accordingly, the 2-1-th micro LED 140a and the 2-2-th micro LED 140b may share the second reflective plate RF2.

The third reflective plate RF3 is disposed so as to enclose the 3-1-th micro LED 150a and the 3-2-th micro LED 150b disposed on the same bank BNK and emitting the same color. Accordingly, the 3-1-th micro LED 150a and the 3-2-th micro LED 150b may share the third reflective plate RF3.

Referring to FIGS. 9A and 9B, the second electrode CE2 may be disposed on the diffusion layer 117a and the plurality of reflective plates RF. For example, the second electrode CE2 may be electrically connected to the plurality of contact electrodes CCE through a contact hole of the diffusion layer 117a. For example, the second electrode CE2 may be disposed on the plurality of micro LEDs ED. A plurality of second electrodes CE2 may be disposed on the diffusion layer and the plurality of micro LEDs ED and is connected to the plurality of micro LEDs ED, respectively. For example, the second electrode CE2 may include a transparent conductive oxide, such as indium tin oxide (ITO) or indium zinc oxide (IZO), but the exemplary embodiments of the present disclosure are not limited thereto. For example, the second electrode CE2 may be disposed to be in contact with the cathode electrode 135.

The second electrode CE2 may continuously extend in a first direction of the substrate 110. Accordingly, the second electrode may be commonly connected to the plurality of pixels PX disposed in the first direction of the substrate 110. For example, the second electrode CE2 may be commonly connected to the plurality of pixels PX.

According to the present disclosure, the second electrode CE2 may continuously extend on the diffusion layer 117a, the plurality of reflective plates RF, and the micro LED ED. Therefore, the second electrode CE2 may be disposed along a shape of the plurality of concave portions G on the diffusion layer 117a. Accordingly, the second electrode CE2 may be in contact with the plurality of reflective plates RF disposed on the plurality of concave portions G, but is not limited thereto.

An upper diffusion layer 117b may be disposed on the second electrode CE2. The upper diffusion layer 117b may be disposed so as to overlap the plurality of micro LEDs ED and the diffusion layer 117a. The upper diffusion layer 117b is disposed above the second electrode CE2 and the plurality of micro LEDs ED so that mura which may be generated in some of the plurality of micro LEDs ED may be improved. For example, when the plurality of micro LEDs ED are transferred onto the substrate 110 of the display apparatus 1000, an area in which the interval between the plurality of micro LEDs ED is not uniform may be caused due to a process deviation. When the interval between the plurality of micro LEDs ED is not uniform, a light emission area of each of the plurality of micro LEDs ED may not be uniformly disposed so that the mura may be visible to a user. Accordingly, the upper diffusion layer 117b which is configured to uniformly diffuse light is configured above the plurality of micro LEDs ED so that light emitted from some micro LED ED which is visible as mura may be reduced. Accordingly, light emitted from the plurality of micro LEDs ED is uniformly diffused by the upper diffusion layer 117b to be extracted to the outside of the display apparatus 1000 so that the luminance uniformity of the display apparatus 1000 may be improved.

The upper diffusion layer 117b may be configured by an organic insulating material in which micro particles are dispersed, but the exemplary embodiments of the present disclosure are not limited thereto. For example, the upper diffusion layer 117b may be configured by siloxane in which micro metal particles, such as titanium dioxide (TiO2) particles, are dispersed, but the exemplary embodiments of the present disclosure are not limited thereto. For example, the upper diffusion layer 117b may be an optical layer or a top optical layer, but the exemplary embodiments of the present disclosure are not limited thereto.

According to the present disclosure, light from the plurality of micro LEDs ED is scattered by micro particles dispersed in the upper diffusion layer 117b to be emitted to the outside of the display apparatus 1000. The upper diffusion layer 117b uniformly mixes light emitted from the plurality of micro LEDs ED to further improve the luminance uniformity of the display apparatus 1000. The light extraction efficiency of the display apparatus 1000 may be improved by light scattered from the plurality of micro particles so that the display apparatus 1000 may be driven at a low power.

In the active area AA, a black matrix BM may be disposed on the second electrode CE2, the diffusion layer 117a, and the top diffusion layer 117b. For example, a contact hole of the diffusion layer 117a may be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels may be suppressed.

For example, the black matrix BM may be configured by an opaque material, but the exemplary embodiments of the present disclosure are not limited thereto. For example, the black matrix BM may be configured by an organic insulating material to which black pigment or black dye is added, but the exemplary embodiments of the present disclosure are not limited thereto.

In the active area AA, a cover layer 118 may be disposed on the black matrix BM. The cover layer 118 may protect configurations below the cover layer 118. For example, the cover layer 118 may be configured by an organic insulating material, but the exemplary embodiments of the present disclosure are not limited thereto. For example, the cover layer 118 may be configured by a photo resist, polyimide (PI), or photo acrylic material, but the exemplary embodiments of the present disclosure are not limited thereto. For example, the cover layer 118 may be an over coating layer or an insulating layer, but the exemplary embodiments of the present disclosure are not limited thereto.

A polarization layer 293 may be disposed on the cover layer 118 by means of the first adhesive layer 291. A cover member 120 may be disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the exemplary embodiments of the present disclosure are not limited thereto.

According to the present disclosure, a plurality of pad electrodes PE may be disposed on the third insulating layer 115c in the second non-active area NA2. For example, at least some of the plurality of pad electrodes PE may be exposed from the passivation layer 116. For example, the plurality of pad electrodes PE may be electrically connected to the 2-4-th connection line 122d through a contact hole of the third insulating layer 115c.

The adhesive layer ACF may be disposed on the plurality of pad electrodes PE. The adhesive layer ACF may be an adhesive layer in which conductive balls are dispersed in an insulating material, but the exemplary embodiments of the present disclosure are not limited thereto. When heat or pressure is applied to the adhesive layer ACF, the conductive balls are electrically connected in a portion applied with the heat or pressure to have a conductive property. The adhesive layer ACF is disposed between the plurality of pad electrodes PE and the flexible circuit board (or flexible film) FCB so that the flexible circuit board (or flexible film) FCB may be attached or bonded to the plurality of pad electrodes PE. For example, the adhesive layer ACF may be anisotropic conductive film (ACF), but the exemplary embodiments of the present disclosure are not limited thereto.

The flexible circuit board (or flexible film) FCB may be disposed on the adhesive layer ACF. The flexible circuit board (or flexible film) FCB may be electrically connected to the plurality of pad electrodes PE through the adhesive layer ACF. Accordingly, a signal output from the flexible circuit board (or flexible film) FCB and the printed circuit board 160 may be transmitted to the pixel driving circuit PD of the active area AA through the plurality of pad electrodes PE, the 2-4-th connection line 122d, the 2-3-th connection line 122c, the 2-2-th connection line 122b, and the 2-1-th connection line 122a.

In order to improve a light emission efficiency of the micro LED in the display apparatus, various methods are used. For example, light emitted from the micro LED is scattered using scattering particles to improve the light emission efficiency. Therefore, the micro particles may be dispersed in the diffusion layer which encloses the micro LED. At this time, the diffusion layer may be patterned to form a contact hole for connecting the micro LED and the pixel driving circuit. However, when the diffusion layer includes micro particles, the micro particles affect the process of coating or patterning the diffusion layer so that more sophisticated control is required during the process. Therefore, the process difficulty may be deepened. Accordingly, there is a problem in that the diffusion layer including micro particles is not disposed in a larger area.

In the display apparatus 1000 according to the exemplary embodiment of the present disclosure, the diffusion layer 117a which is disposed so as to enclose the plurality of micro LEDs ED may not include micro particles. Instead, a plurality of concave portions G which is disposed so as to enclose the plurality of micro LEDs ED may be formed on the diffusion layer 117a and the plurality of reflective plates RF may be disposed in each of the plurality of concave portions G.

Therefore, the process difficulty due to the micro particles may be alleviated and the light extraction efficiency may be improved by a relatively easy process using the plurality of reflective plates RF. That is, in the display apparatus 1000 according to the exemplary embodiment of the present disclosure, the process optimization may be implemented and the display apparatus with a high luminance may be implemented.

In the meantime, in order to improve the light emission efficiency of the micro LED, the reflective plate using a material having an excellent reflectivity may be disposed in an optical path of the micro LED. That is, light which is directed to the side surface is reflected using the reflective plate to change the path of the light to be directed to the front surface, thereby improving a light emission efficiency. However, also in this case, when the reflective plate is applied to each micro LED to be disposed so as to enclose each micro LED, there is a problem in that a plurality of reflective plates needs to be disposed in a narrow area. For example, when the micro LED is disposed on the bank, a space for placing a reflective plate between the banks needs to be ensured so that there is a drawback in that an unnecessary space is increased.

This may be especially a problem in a high pixel per inch (PPI) display apparatus for implementing a high resolution. That is, in the high resolution display apparatus having a high PPI, a size of one pixel is small so that the increase in the area occupied by the bank may greatly affect the aperture ratio.

Further, in the display apparatus 1000 according to the exemplary embodiment of the present disclosure, the plurality of concave portions G are disposed along a boundary of the bank BNK. Therefore, the plurality of reflective plates RF disposed on the plurality of concave portions G may also be disposed along the boundary of the bank BNK. That is, each of the plurality of reflective plates RF may be disposed so as to enclose the micro LED ED disposed on the same bank BNK. That is, two micro LEDs which are disposed on the same bank BNK and emit the same color light may share the plurality of reflective plates RF.

That is, in the display apparatus 1000 according to the exemplary embodiment of the present disclosure, the plurality of reflective plates RF are disposed so as to enclose at least two micro LEDs ED along the boundary of the bank BNK. Therefore, an unnecessary space required to apply a reflective plate RF in each micro LED ED between the banks BNK may be minimized. Accordingly, the increase of the area of the bank BNK is not necessary so that the integration degree of the pixel is improved to implement the high resolution.

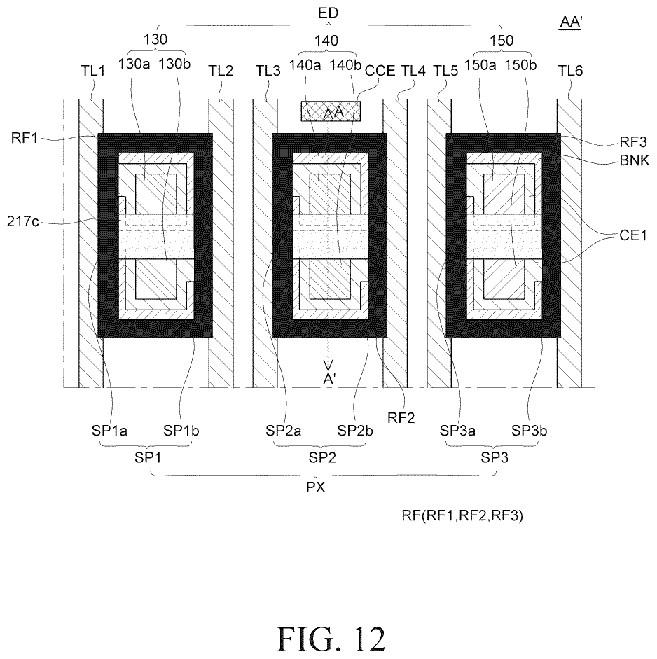

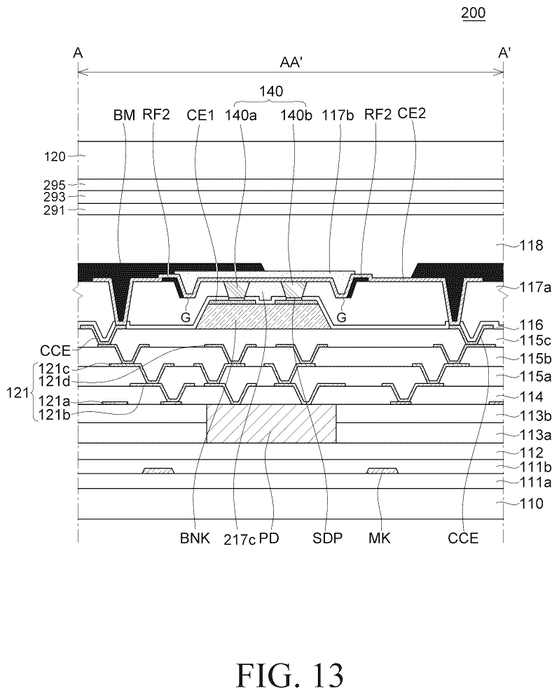

FIG. 12 is a plan view of a display apparatus according to another exemplary embodiment of the present disclosure. FIG. 13 is a cross-sectional view of a display apparatus according to another exemplary embodiment of the present disclosure. A display apparatus of FIGS. 12 and 13 has components which are substantially the same as the display apparatus of FIGS. 1 to 11 except a side wall diffusion layer 217c of an active area AA′ so that a redundant description will be omitted.

Referring to FIGS. 12 and 13, the side wall diffusion layer 217c may be disposed between the plurality of micro LEDs ED on the bank BNK. The side wall diffusion layer 217c may be disposed between the two micro LEDs ED on the bank. The side wall diffusion layer 217c may be disposed only between the two micro LEDs.

The side wall diffusion layer 217c may include an organic insulating material in which micro particles are dispersed, but the exemplary embodiments of the present disclosure are not limited thereto. For example, the side wall diffusion layer 217c may be configured by siloxane in which micro metal particles, such as titanium dioxide (TiO2) particles, are dispersed, but the exemplary embodiments of the present disclosure are not limited thereto.

Light from the plurality of micro LEDs ED is scattered by micro particles dispersed in the side wall diffusion layer 217c to be emitted to the outside of the display apparatus. Accordingly, the side wall diffusion layer 217c may improve extraction efficiency of light emitted from the plurality of micro LEDs ED.

In the meantime, the side wall diffusion layer 217c including micro particles may be disposed in a minimum area required to ensure the easiness of the process. For example, the side wall diffusion layer 217c may be disposed only between the plurality of micro LEDs ED on the bank BNK. For example, the side wall diffusion layer 217c may be spaced apart from each other, between a 1-1-th micro LED 130a and a 1-2-th micro LED 130b, between a 2-1-th micro LED 140a and a 2-2-th micro LED 140b, and between a 3-1-th micro LED 150a and a 3-2-th micro LED 150b on the bank BNK.

That is, the side wall diffusion layer 217c may be disposed to be spaced apart from each other in each of the first sub pixel SP1, the second sub pixel SP2, and the third sub pixel SP3. Therefore, the reflective plates RF may be disposed so as to enclose the side wall diffusion layer 217c.

For example, the first reflective plate RF may be disposed so as to enclose the side wall diffusion layer 217c disposed in the first sub pixel SP1. The second reflective plate RF2 may be disposed so as to enclose the side wall diffusion layer 217c disposed in the second sub pixel SP2. The third reflective plate RF3 may be disposed so as to enclose the side wall diffusion layer 217c disposed in the third sub pixel SP3, but is not limited thereto.

In the display apparatus according to another exemplary embodiment of the present disclosure, a plurality of concave portions G which are disposed so as to enclose the plurality of micro LEDs ED may be formed and the plurality of reflective plates RF may be disposed in each of the plurality of concave portions G. At this time, the plurality of concave portions G are disposed along the boundary of the bank BNK so that the plurality of reflective plates RF disposed on the plurality of concave portions G may also be disposed along the boundary of the bank BNK. That is, each of the plurality of reflective plates RF may be disposed so as to enclose the micro LED ED disposed on the same bank BNK. That is, two micro LEDs which are disposed on the same bank BNK and emit the same color light may share the plurality of reflective plates RF.

That is, in the display apparatus according to another exemplary embodiment of the present disclosure, the plurality of reflective plates RF is disposed to enclose at least two micro LEDs ED along the boundary of the bank BNK. Therefore, an unnecessary space required to apply a reflective plate RF in each micro LED ED between the banks BNK may be minimized. Accordingly, the increase of the area of the bank BNK is not necessary so that the integration degree of the pixel is improved to implement the high resolution.

In the display apparatus according to another exemplary embodiment of the present disclosure, the side wall diffusion layer 217c including micro particles may be disposed between the plurality of micro LEDs ED. For example, the side wall diffusion layer 217c may be disposed to be spaced apart in each of the plurality of sub pixels. For example, the side wall diffusion layer 217c may be disposed to be spaced apart, between the 1-1-th micro LED 130a and the 1-2-th micro LED 130b, between the 2-1-th micro LED 140a and the 2-2-th micro LED 140b, and between the 3-1-th micro LED 150a and the 3-2-th micro LED 150b. That is, the side wall diffusion layer 217c is disposed only in a required minimum area to alleviate a process difficulty due to the micro particles and improve the light extraction efficiency. Therefore, the process optimization may be implemented and a display apparatus with a high luminance may be implemented.

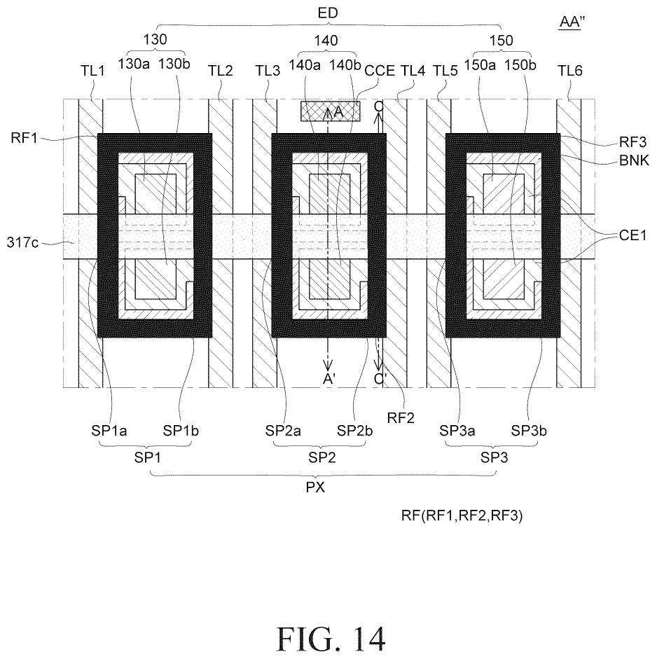

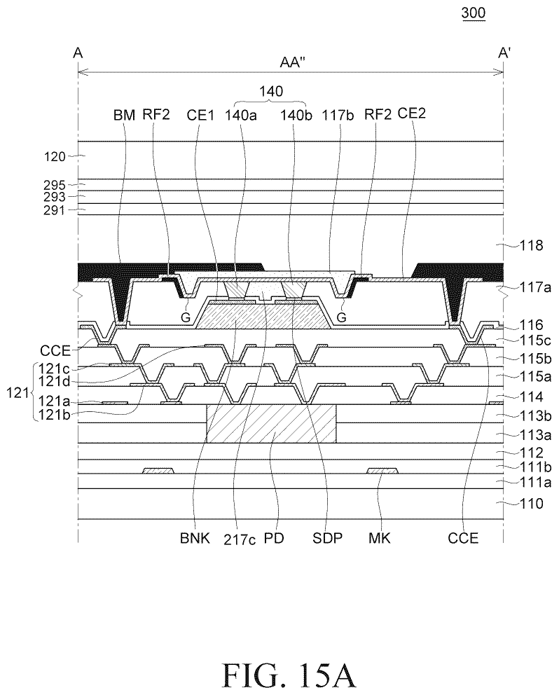

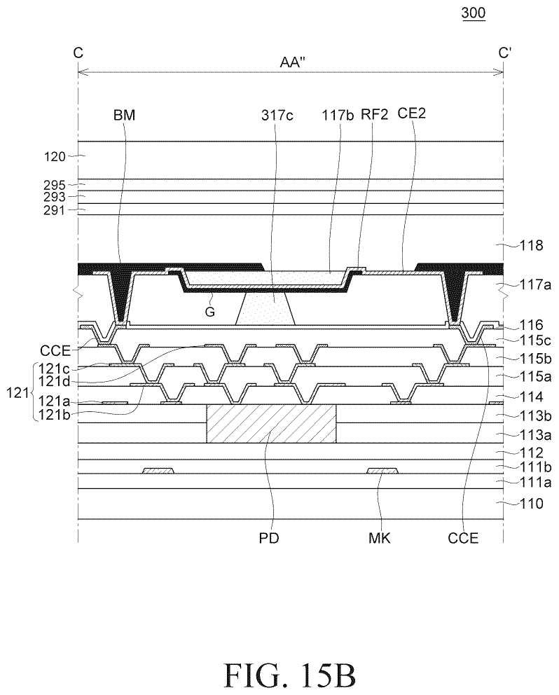

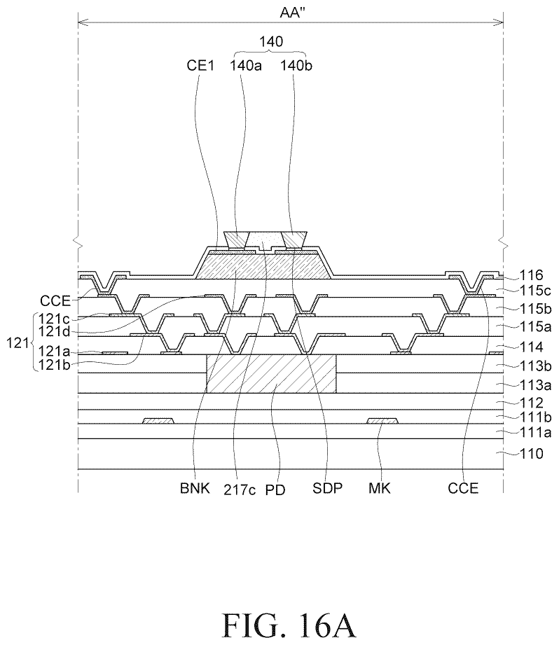

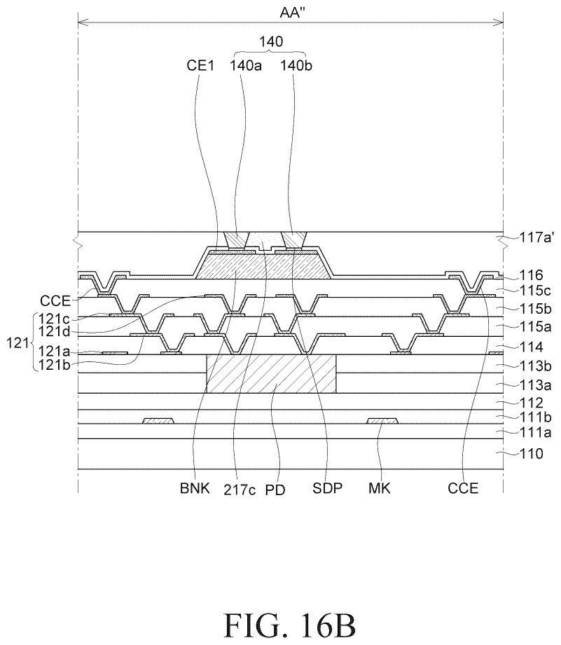

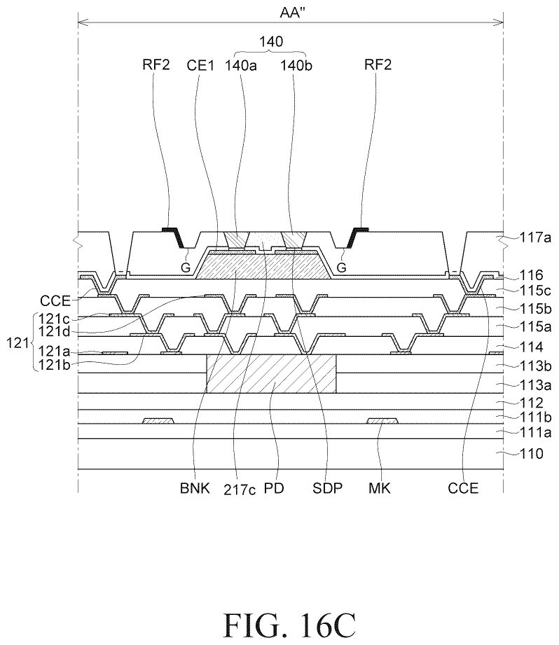

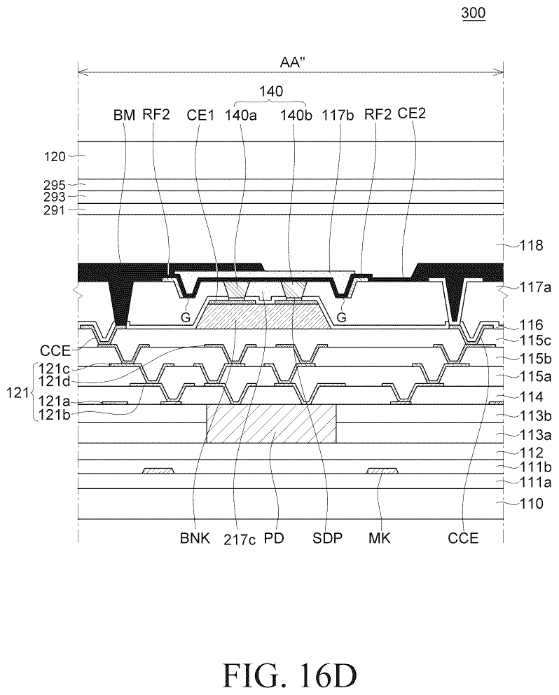

FIG. 14 is a plan view of a display apparatus according to still another exemplary embodiment of the present disclosure. FIGS. 15A and 15B are cross-sectional views of a display apparatus according to still another exemplary embodiment of the present disclosure. FIGS. 16A to 16D are process diagrams for explaining a manufacturing method of a display apparatus according to still another exemplary embodiment of the present disclosure. For example, FIG. 15A is a cross-sectional view of an active area AA″ taken along A-A′ of FIG. 14. For example, FIG. 15B is a cross-sectional view of an active area AA″ taken along C-C′ of FIG. 14. A display apparatus of FIGS. 14 to 16D has components which are substantially the same as the display apparatus of FIGS. 12 and 13 except a side wall diffusion layer 317c so that a redundant description will be omitted.

Referring to FIGS. 14 to 15B, the plurality of sub pixels may share the side wall diffusion layer 317c. That is, the side wall diffusion layer 317c may be continuously disposed in the first sub pixel SP1, the second sub pixel SP2, and the third sub pixel SP3.

For example, the side wall diffusion layer 317c may be continuously disposed between the plurality of micro LEDs ED on the bank BNK of the first sub pixel SP1, the second sub pixel SP2, and the third sub pixel SP3. Therefore, when the banks BNK are spaced apart from each other in the row direction and extend in the column direction, the side wall diffusion layers 317c may extend in the row direction and be spaced apart from each other in the column direction.

That is, the side wall diffusion layer 317c may not only be disposed between the plurality of micro LEDs ED on the bank BNK, but also extend onto the third insulating layer 115c where the bank BNK is disposed. The plurality of banks BNK may extend in a first direction, and the side wall diffusion layer may extend onto the plurality of insulating layers to extend in a second direction, and may be disposed to be spaced apart in the first direction Therefore, the side wall diffusion layer 317c may be disposed so as to overlap the reflective plates RF, but is not limited thereto.

In the meantime, in FIG. 15B, it is illustrated that the passivation layer 116 is disposed on the third insulating layer 115c so that the side wall diffusion layer 317c is disposed on the passivation layer 116. However, the present disclosure is not limited thereto, and for example, when the passivation layer 116 is not disposed, the side wall diffusion layer 317c may be disposed on the third insulating layer 115c.

That is, in the display apparatus according to still another exemplary embodiment of the present disclosure, the side wall diffusion layer 317c may not be patterned in each sub pixel, but the plurality of sub pixels may share the side wall diffusion layer 317c. That is, the side wall diffusion layer 317c may be continuously disposed, between the 1-1-th micro LED 130a and the 1-2-th micro LED 130b, between the 2-1-th micro LED 140a and the 2-2-th micro LED 140b, and between the 3-1-th micro LED 150a and the 3-2-th micro LED 150b, but is not limited thereto.

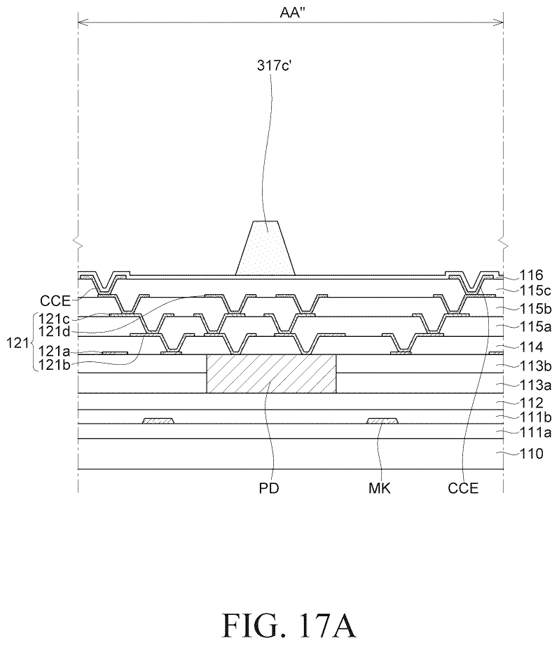

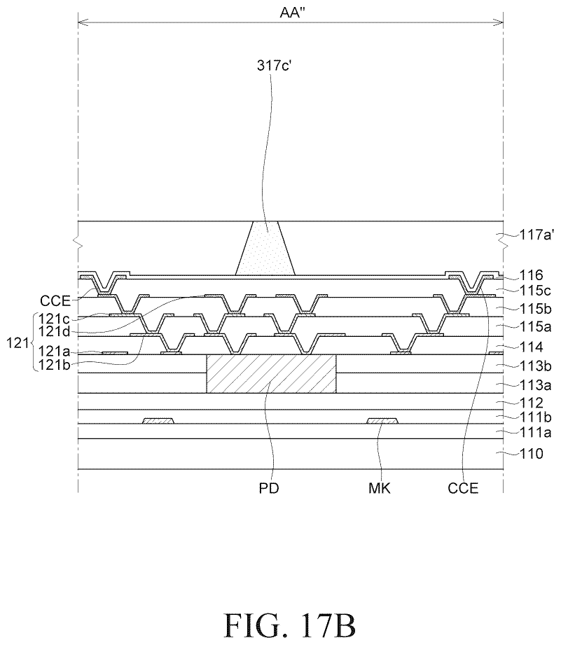

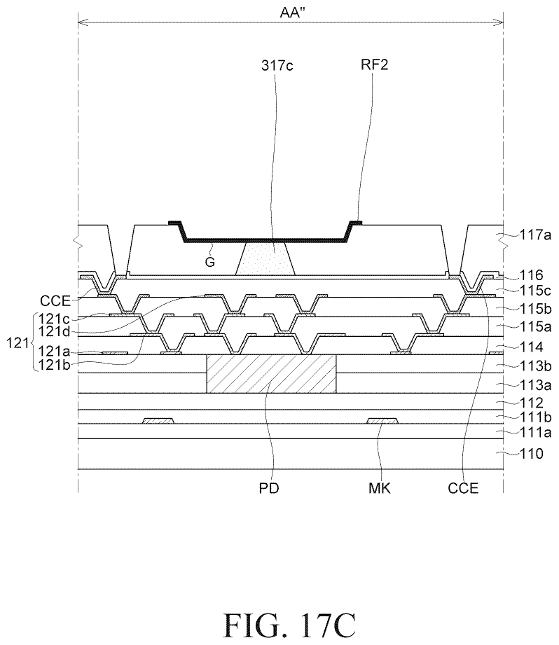

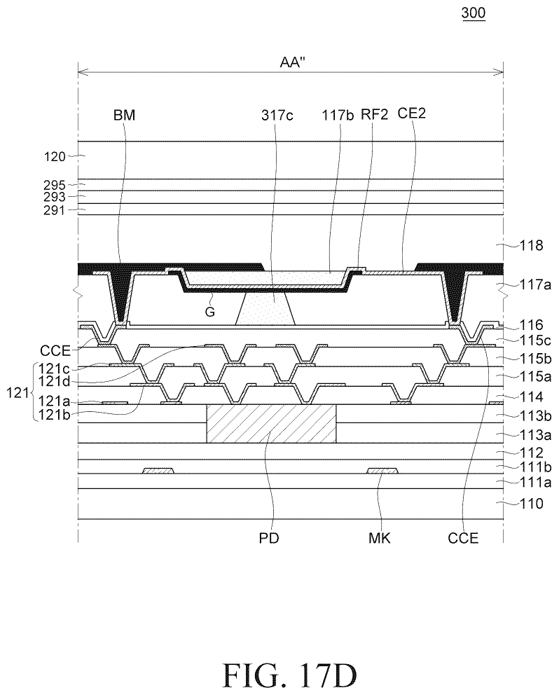

Hereinafter, a process diagram of a manufacturing method of a display apparatus according to still another exemplary embodiment of the present disclosure will be described in detail with reference to FIGS. 16A to 17D.

FIGS. 16A to 16D are process diagrams of a manufacturing method of a display apparatus according to still another exemplary embodiment of the present disclosure. FIGS. 17A to 17D are process diagrams of a manufacturing method of a display apparatus according to still another exemplary embodiment of the present disclosure. For example, FIGS. 16A to 16D are process diagrams taken along A-A′ of FIG. 14 and FIGS. 17A to 17D are process diagrams along C-C′ of FIG. 14.

First, referring to FIGS. 16A and 17A, two micro LEDs which emit the same color light, for example, a 2-1-th micro LED 140a and a 2-2-th micro LED 140b may be disposed on the plurality of banks BNK.

An initial side wall diffusion layer 317c′ may be disposed between the 2-1-th micro LED 140a and the 2-2-th micro LED 140b on the bank BNK. At this time, the initial side wall diffusion layer 317c′ may be commonly disposed in the plurality of sub pixels. Therefore, referring to FIG. 17A, the initial side wall diffusion layer 317c′ may extend on the passivation layer 116.

In the meantime, in FIG. 17A, it is illustrated that the passivation layer 116 is disposed on the third insulating layer 115c so that the initial side wall diffusion layer 317c′ is disposed on the passivation layer 116. However, the present disclosure is not limited thereto, and for example, when the passivation layer 116 is not disposed, the initial side wall diffusion layer 317c′ may be disposed on the third insulating layer 115c. In the meantime, in a process to be described below, a part of the initial side wall diffusion layer 317c′ is removed to form a side wall diffusion layer 317c.

Next, referring to FIGS. 16B and 17B, an initial diffusion layer 117a′ may be disposed. The initial diffusion layer 117a′ may be disposed so as to enclose the second micro LED 140, the initial side wall diffusion layer 317c′, and the bank BNK to planarize an area where the second micro LED 140 is disposed and a surrounding area.

Next, referring to FIGS. 16C and 17C, a part of the initial diffusion layer 117a′ is removed to form a diffusion layer 117a including a plurality of concave portions G. That is, the plurality of concave portions G may be an intagliated pattern obtained by partially removing the initial diffusion layer 117a′ in a thickness direction, but is not limited thereto.

At the same time as the formation of the plurality of concave portions G, the initial diffusion layer 117a′ is partially removed to form a contact hole. For example, a contact hole which exposes the contact electrode CCE may be formed to connect the contact electrode CCE and the second electrode CE2, but is not limited thereto.

At this time, when the concave portion G and the contact hole which are formed by partially removing the initial diffusion layer 117a′ are compared, a vertical width of the concave portion G may be smaller than a vertical width of the contact hole. The contact hole exposes the contact electrode CCE so that the vertical width of the contact hole may be equal to the vertical width of the diffusion layer 117a. In contrast, the vertical width of the concave portion G may be equal to or smaller than the vertical width of the micro LED ED.

For example, a height of the highest end of the concave portion G may be equal to or lower than a height of a top surface of the micro LED ED. A height of a lowest end of the concave portion G may be higher than a height of a lowest end of the contact hole of the diffusion layer 117a, that is, a top surface of the contact electrode CCE, but is not limited thereto.

In the meantime, when the initial diffusion layer 117a′ is partially removed, a part of the initial side wall diffusion layer 317c′ is also removed to form the side wall diffusion layer 317c.

In order to improve the light extraction efficiency of the second micro LED 140, the plurality of reflective plates RF may be disposed on the plurality of concave portions G of the diffusion layer 117a. The plurality of reflective plates RF may be disposed on the optical path of the second micro LED 140 to change the optical path of the second micro LED 140. Therefore, the plurality of reflective plates RF may be spaced apart from the second micro LED 140 with a predetermined interval. For example, the plurality of reflective plates RF may be disposed in a concave portion G which is further from the second micro LED 140, among the plurality of concave portions G, but is not limited thereto.

Further, referring to FIG. 17C, the side wall diffusion layer 317c extends not only on the bank BNK, but also on the passivation layer 116 to overlap the plurality of reflective plates RF, but is not limited thereto.

Finally, referring to FIGS. 16D and 17D, components including the second electrode CE2 are disposed on the second micro LED 140 and the diffusion layer 117a to complete the manufacturing process of the display apparatus.

For example, the second electrode CE2 may be disposed along a shape of the plurality of concave portions G on the diffusion layer 117a. Accordingly, the second electrode CE2 may be in contact with the plurality of reflective plates RF disposed on the plurality of concave portions G, but is not limited thereto.

In the display apparatus according to another exemplary embodiment of the present disclosure, a plurality of concave portions G which is disposed so as to enclose the plurality of micro LEDs ED may be formed and the plurality of reflective plates RF may be disposed in each of the plurality of concave portions G. At this time, the plurality of concave portions G are disposed along the boundary of the bank BNK so that the plurality of reflective plates RF disposed on the plurality of concave portions G may also be disposed along the boundary of the bank BNK. That is, each of the plurality of reflective plates RF may be disposed so as to enclose the two micro LEDs ED disposed on the same bank BNK and emitting the same color light. That is, two micro LEDs which are disposed on the same bank BNK and emit the same color light may share the plurality of reflective plates RF.

That is, in the display apparatus according to another exemplary embodiment of the present disclosure, the plurality of reflective plates RF are disposed so as to enclose at least two micro LEDs ED along the boundary of the bank BNK. Therefore, an unnecessary space required to apply a reflective plate RF in each micro LED ED between the banks BNK may be minimized. Accordingly, the increase of the area of the bank BNK is not necessary so that the integration degree of the pixel is improved to implement the high resolution.

In the display apparatus according to another exemplary embodiment of the present disclosure, the side wall diffusion layer 217c including micro particles may be disposed between the plurality of micro LEDs ED. For example, the side wall diffusion layer 217c may be disposed to be spaced apart from each other in each of the plurality of sub pixels. For example, the side wall diffusion layer 217c may be disposed between the 1-1-th micro LED 130a and the 1-2-th micro LED 130b, between the 2-1-th micro LED 140a and the 2-2-th micro LED 140b, and between the 3-1-th micro LED 150a and the 3-2-th micro LED 150b. That is, the side wall diffusion layer 217c is disposed only in a required minimum area to alleviate a process difficulty due to the micro particles and improve the light extraction efficiency. Therefore, the process optimization may be implemented and a display apparatus with a high luminance may be improved.

Specifically, in the display apparatus according to still another exemplary embodiment of the present disclosure, the plurality of sub pixels may share a side wall diffusion layer 317c including micro particles. For example, the side wall diffusion layer 317c may be simultaneously disposed, between the 1-1-th micro LED 130a and the 1-2-th micro LED 130b, between the 2-1-th micro LED 140a and the 2-2-th micro LED 140b, and between the 3-1-th micro LED 150a and the 3-2-th micro LED 150b, in the plurality of sub pixels. That is, a process of patterning the side wall diffusion layer 317c to be disposed in each sub pixel may be omitted. Therefore, precise control required for the patterning process due to the micro particles of the side wall diffusion layer 317c is not necessary so that deepening of the process difficulty may be suppressed. Further, the process cost and time for the patterning process of the side wall diffusion layer 317c may be saved.

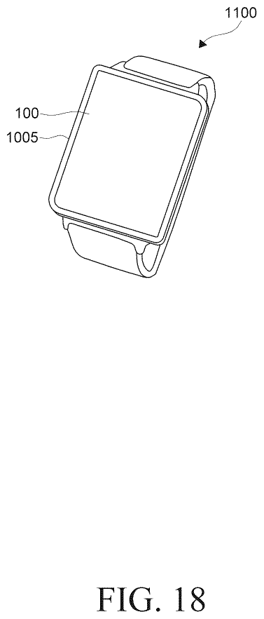

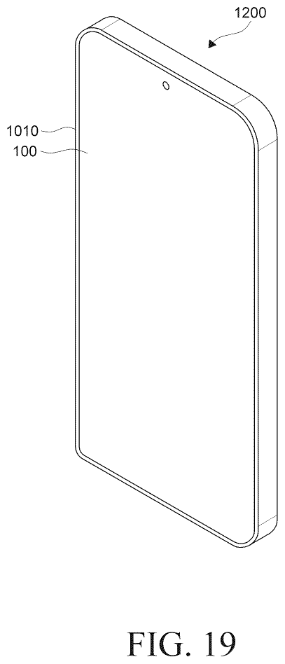

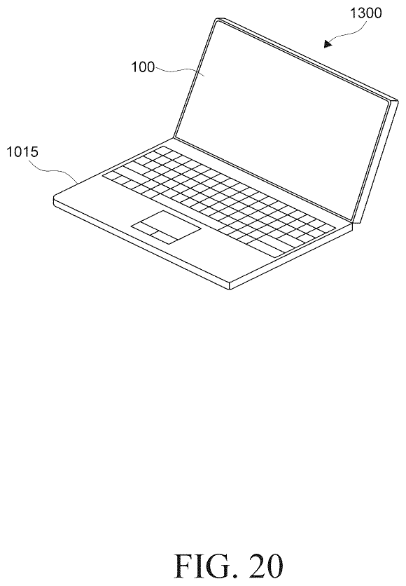

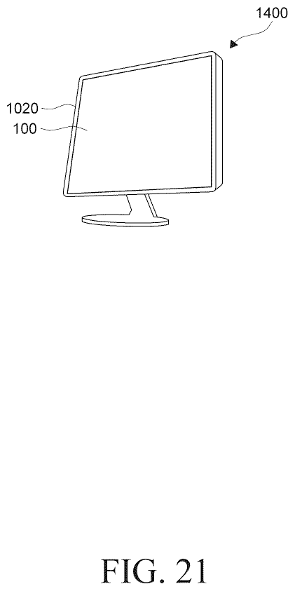

FIGS. 18 to 21 are diagrams illustrating apparatuses to which the display apparatus according to exemplary embodiments of the present disclosure is applied.

Referring to FIGS. 18 to 21, the display apparatus 1000 according to the exemplary embodiments of the present disclosure may be included in various apparatuses or electronic apparatuses. For example, referring to FIGS. 18 to 21, various electronic apparatuses may include a wearable device 1100, a mobile device 1200, a laptop 1300, and a monitor, or TV 1400, but the exemplary embodiments of the present disclosure are not limited thereto.

Each of the wearable device 1100, the mobile device 1200, the laptop 1300, and the monitor or the TV 1400 may respectively include case parts 1005, 1010, 1015, and 1020 and the display panel 100, 200, 300 and the display apparatus 1000 according to the exemplary embodiments of the present disclosure described in FIGS. 1 to 17d.

For example, the display apparatus according to an exemplary embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop PC, a laptop PC, a netbook computer, a workstation, a navigation system, a vehicle display apparatus, a theater display apparatus, a television, a wallpaper apparatus, a signage apparatus, a game console, a laptop, a monitor, a camera, a camcorder, home appliances, etc.

The exemplary embodiments of the present disclosure can also be described as follows:

According to an aspect of the present disclosure, there is provided a display apparatus. The display apparatus includes a substrate, a pixel driving circuit disposed on the substrate, a plurality of insulating layers disposed on the pixel driving circuit, a bank disposed on the plurality of insulating layers, a plurality of micro LEDs which is disposed on the bank, and is electrically connected to the pixel driving circuit, a diffusion layer which is disposed on the plurality of insulating layers and is disposed so as to enclose the bank and the plurality of micro LEDs and includes a concave portion disposed along a boundary of the bank and a reflective plate disposed on the concave portion.

The reflective plate may be disposed on a side surface which is further from the plurality of micro LEDs, among side surfaces of the concave portion.

The reflective plate may be disposed to extend to a top surface of the diffusion layer.

The plurality of micro LEDs may include two micro LEDs which are disposed on the bank and emit the same color. The reflective plate may be disposed so as to enclose the two micro LEDs.

The two micro LEDs may share the reflective plate.

The display apparatus may further include a side wall diffusion layer which is disposed between the two micro LEDs on the bank and includes an organic insulating material in which micro particles are dispersed.

The side wall diffusion layer may be disposed only between the two micro LEDs.

The reflective plate may be disposed so as to enclose the side wall diffusion layer.

The side wall diffusion layer may extend onto the plurality of insulating layers to overlap the reflective plate.

The display apparatus may further include a plurality of first electrodes which are disposed on the bank and is electrically connected to the plurality of micro LEDs, respectively, and a plurality of second electrodes which are disposed on the diffusion layer and the plurality of micro LEDs and is connected to the plurality of micro LEDs, respectively. The plurality of second electrodes may be disposed along a shape of the concave portion on the diffusion layer.

The plurality of second electrodes may be in contact with the reflective plate.

The display apparatus may further include an upper diffusion layer which is disposed on the plurality of second electrodes and includes an organic insulating material in which micro particles are dispersed.

Each of the plurality of micro LEDs may include an anode electrode, a first semiconductor layer disposed on the anode electrode, an active layer disposed on the first semiconductor layer, a second semiconductor layer disposed on the active layer and a cathode electrode disposed on the second semiconductor layer.

The display apparatus may further include a first electrode which is disposed below the plurality of micro LEDs to electrically connect the pixel driving circuit and the anode electrodes of the plurality of micro LEDs and a solder pattern which are disposed between the first electrode and the anode electrode. The first electrode and the anode electrode may be electrically connected by eutectic bonding using the solder pattern.

According to another embodiment of the present disclosure, there is provided a display apparatus. The display apparatus includes a substrate including an active area including a plurality of sub pixels and a non-active area which encloses the active area, a pixel driving circuit disposed on the substrate, a plurality of insulating layers disposed on the pixel driving circuit, a plurality of banks disposed on the plurality of insulating layers, a plurality of micro LEDs which are disposed on the plurality of banks and are disposed in each of the plurality of sub pixels, a diffusion layer which is disposed on the plurality of insulating layers and the banks and is disposed so as to enclose the plurality of micro LEDs and a plurality of reflective plates disposed on the diffusion layer. The diffusion layer includes a plurality of concave portions which is disposed so as to correspond to an outer contour of each of the plurality of banks on a plane and the plurality of reflective plates is disposed in the plurality of concave portions, respectively.

The plurality of micro LEDs may include a 1-1-th micro LED and a 1-2-th micro LED which are disposed on the same bank, among the plurality of banks, and emit the same color light, a 2-1-th micro LED and a 2-2-th micro LED which are disposed on the same bank, among the plurality of banks, and emit the same color light and a 3-1-th micro LED and a 3-2-th micro LED which are disposed on the same bank, among the plurality of banks, and emit the same color light. Each of the plurality of reflective plates may be disposed so as to enclose two micro LEDs which emit the same color light.

The plurality of reflective plates may include a first reflective plate which encloses the 1-1-th micro LED and the 1-2-th micro LED, a second reflective plate which encloses the 2-1-th micro LED and the 2-2-th micro LED and a third reflective plate which encloses the 3-1-th micro LED and the 3-2-th micro LED.

The first reflective plate, the second reflective plate, and the third reflective plate may be disposed to be spaced apart from each other.

The plurality of banks may extend in a first direction and the plurality of reflective plates may extend in the first direction and be spaced apart from each other in a second direction.

The display apparatus may further include a side wall diffusion layer which is disposed between the 1-1-th micro LED and the 1-2-th micro LED, between the 2-1-th micro LED and the 2-2-th micro LED, and between the 3-1-th micro LED and the 3-2-th micro LED, on the plurality of banks, and includes micro particles.

The side wall diffusion layer may be disposed to be spaced apart between the 1-1-th micro LED and the 1-2-th micro LED, between the 2-1-th micro LED and the 2-2-th micro LED, and between the 3-1-th micro LED and the 3-2-th micro LED.

The plurality of banks may extend in a first direction and the side wall diffusion layer may extend onto the plurality of insulating layers to extend in a second direction and be disposed to be spaced apart in the first direction.

Each of the plurality of micro LEDs may include an anode electrode, a first semiconductor layer disposed on the anode electrode, an active layer disposed on the first semiconductor layer, a second semiconductor layer disposed on the active layer, and a cathode electrode disposed on the second semiconductor layer and may have a vertical type structure.

The display apparatus may further include a first electrode disposed below the plurality of micro LEDs and a solder pattern which is disposed between the first electrode and the anode electrode. The anode electrode may be bonded to the first electrode by eutectic bonding using the solder pattern.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display apparatus, comprising:
a substrate;
a pixel driving circuit on the substrate;
a plurality of insulating layers on the pixel driving circuit;
a bank on the plurality of insulating layers;
a plurality of micro light emitting diodes (LEDs) on the bank, the plurality of micro LEDs electrically connected to the pixel driving circuit;
a diffusion layer on the plurality of insulating layers and enclosing the bank and the plurality of micro LEDs, the diffusion layer including a concave portion along a boundary of the bank; and
a reflective plate on the concave portion of the diffusion layer.

2. The display apparatus according to claim 1, wherein the reflective plate is on a side surface which is further from the plurality of micro LEDs, among side surfaces of the concave portion.

3. The display apparatus according to claim 2, wherein the reflective plate extends to a top surface of the diffusion layer.

4. The display apparatus according to claim 1, wherein the plurality of micro LEDs include two micro LEDs on the bank and emit a same color and the reflective plate encloses the two micro LEDs.

5. The display apparatus according to claim 4, wherein the two micro LEDs share the reflective plate.

6. The display apparatus according to claim 4, further comprising:
a side wall diffusion layer between the two micro LEDs on the bank, the side wall diffusion layer including an organic insulating material in which micro particles are dispersed.

7. The display apparatus according to claim 6, wherein the side wall diffusion layer is between the two micro LEDs.

8. The display apparatus according to claim 7, wherein the reflective plate encloses the side wall diffusion layer.

9. The display apparatus according to claim 6, wherein the side wall diffusion layer extends onto the plurality of insulating layers and overlaps the reflective plate.

10. The display apparatus according to claim 1, further comprising:
a plurality of first electrodes on the bank, the plurality of first electrodes electrically connected to the plurality of micro LEDs; and
a plurality of second electrodes on the diffusion layer and the plurality of micro LEDs, the plurality of second electrodes connected to the plurality of micro LEDs,
wherein the plurality of second electrodes are along a shape of the concave portion on the diffusion layer.

11. The display apparatus according to claim 10, wherein the plurality of second electrodes are in contact with the reflective plate.

12. The display apparatus according to claim 10, further comprising:
an upper diffusion layer on the plurality of second electrodes, the upper diffusion layer including an organic insulating material in which micro particles are dispersed.

13. The display apparatus according to claim 1, wherein each of the plurality of micro LEDs includes:
an anode electrode;
a first semiconductor layer on the anode electrode;
an active layer on the first semiconductor layer;
a second semiconductor layer on the active layer; and
a cathode electrode on the second semiconductor layer.

14. The display apparatus according to claim 13, further comprising:
a first electrode below the plurality of micro LEDs and electrically connecting the pixel driving circuit and anode electrodes of the plurality of micro LEDs; and
a solder pattern between the first electrode and the anode electrode,
wherein the first electrode and the anode electrode are electrically connected using the solder pattern.

15. A display apparatus, comprising:
a substrate including an active area that comprises a plurality of sub pixels and a non-active area that encloses the active area;
a pixel driving circuit on the substrate;
a plurality of insulating layers on the pixel driving circuit;
a plurality of banks on the plurality of insulating layers;
a plurality of micro light emitting diodes (LEDs) on the plurality of banks, the plurality of micro LEDs in each of the plurality of sub pixels;
a diffusion layer on the plurality of insulating layers and the banks, the diffusion layer enclosing the plurality of micro LEDs; and
a plurality of reflective plates on the diffusion layer,
wherein the diffusion layer includes a plurality of concave portions that correspond to an outer contour of each of the plurality of banks on a plane and the plurality of reflective plates are in the plurality of concave portions, respectively.

16. The display apparatus according to claim 15, wherein the plurality of micro LEDs include:
a 1-1-th micro LED and a 1-2-th micro LED which are on a same bank, among the plurality of banks, and emit a same color light;
a 2-1-th micro LED and a 2-2-th micro LED which are on a same bank, among the plurality of banks, and emit a same color light; and
a 3-1-th micro LED and a 3-2-th micro LED which are on a same bank, among the plurality of banks, and emit a same color light, and
each of the plurality of reflective plates enclose two micro LEDs which emit a same color light.

17. The display apparatus according to claim 16, wherein the plurality of reflective plates include:
a first reflective plate that encloses the 1-1-th micro LED and the 1-2-th micro LED;
a second reflective plate that encloses the 2-1-th micro LED and the 2-2-th micro LED; and
a third reflective plate that encloses the 3-1-th micro LED and the 3-2-th micro LED.

18. The display apparatus according to claim 17, wherein the first reflective plate, the second reflective plate, and the third reflective plate are spaced apart from each other.

19. The display apparatus according to claim 16, wherein the plurality of banks extend in a first direction and the plurality of reflective plates extend in the first direction and are spaced apart from each other in a second direction.

20. The display apparatus according to claim 16, further comprising:
a side wall diffusion layer between the 1-1-th micro LED and the 1-2-th micro LED, between the 2-1-th micro LED and the 2-2-th micro LED, and between the 3-1-th micro LED and the 3-2-th micro LED, the side wall diffusion layer on the plurality of banks and includes micro particles.

21. The display apparatus according to claim 20, wherein the side wall diffusion layer is spaced apart between the 1-1-th micro LED and the 1-2-th micro LED, between the 2-1-th micro LED and the 2-2-th micro LED, and between the 3-1-th micro LED and the 3-2-th micro LED.

22. The display apparatus according to claim 20, wherein the plurality of banks extend in a first direction and the side wall diffusion layer extends onto the plurality of insulating layers and extends in a second direction and is spaced apart in the first direction.

23. The display apparatus according to claim 15, wherein each of the plurality of micro LEDs includes an anode electrode, a first semiconductor layer on the anode electrode, an active layer on the first semiconductor layer, a second semiconductor layer on the active layer, and a cathode electrode on the second semiconductor layer, and each micro LED having a vertical type structure.

24. The display apparatus according to claim 23, further comprising:
a first electrode below the plurality of micro LEDs; and
a solder pattern between the first electrode and the anode electrode,
wherein the anode electrode is connected to the first electrode using the solder pattern.
